(19) United States
(12) Patent Application Publication
(10) Pub. No.: US 2017/0012066 A1
(43) Pub. Date: Jan. 12, 2017

(54) IMAGE SENSOR HAVING CONVERSION DEVICE ISOLATION LAYER DISPOSED IN PHOTOELECTRIC CONVERSION DEVICE

(71) Applicant: Samsung Electronics Co., Ltd., Suwon-si (KR)

(72) Inventors: Hyuksoon CHOI, Hwaseong-si (KR); Jungchak AHN, Yongin-si (KR); Hyuk AN, Seoul (KR); Kyungho LEE, Suwon-si (KR)

(21) Appl. No.: 15/090,989

(22) Filed: Apr. 5, 2016

(30) Foreign Application Priority Data
Jul. 8, 2015 (KR) 10-2015-0097238

(51) Int. Cl. H01L 27/146

(52) U.S. Cl. CPC H01L 27/1463; H01L 27/14645; H01L 27/14636

(57) ABSTRACT

An image sensor includes a first conductivity type first impurity region surrounded by a pixel isolation layer surrounds; a first conversion device isolation layer intersecting the first impurity region in a first direction; a second conductivity type second impurity region disposed on a first side surface of the first conversion device isolation layer; a second conductivity type third impurity region disposed on a second side surface of the first conversion device isolation layer opposite the first side surface; and a second conversion device isolation layer intersecting the first impurity region in a second direction perpendicular to the first direction. The second impurity region and the third impurity region are disposed inside the first impurity region.

### CROSS-REFERENCE TO RELATED APPLICATION

This application claims priority under 35 U.S.C. §119 to Korean Patent Application No. 10-2015-0097238 filed on Jul. 8, 2015, the disclosure of which is hereby incorporated by reference in its entirety.

### BACKGROUND

Field

The inventive concepts relates to an image sensor including a conversion device isolation layer intersecting a photoelectric conversion device.

Description of Related Art

An image sensor includes a photoelectric conversion device vertically overlapping a pixel region and a microlens disposed on the photoelectric conversion device. The image sensor may further include a conversion device isolation layer intersecting the photoelectric conversion device for autofocusing. Light focused by the microlens may be diffused and reflected by the conversion device isolation layer. The light diffused and reflected by the conversion device isolation layer may cause a cross-talk.

### SUMMARY

Example embodiments of the inventive concepts provide an image sensor in which a cross-talk caused by a conversion device isolation layer is uniformly generated in a corresponding one of adjacent pixel regions.

Other example embodiments of the inventive concepts provide an image sensor in which light diffused and reflected by a conversion device isolation layer is uniformly applied to a corresponding one of adjacent pixel regions.

The technical objectives of the inventive concepts are not limited to the above disclosure, and other objectives may become apparent to those of ordinary skill in the art based on the following descriptions.

In accordance with an aspect of the inventive concepts, an image sensor includes a first conductivity type first impurity region surrounded by a pixel isolation layer; a first conversion device isolation layer intersecting the first impurity region in a first direction and including a first side surface and a second side surface opposite the first side surface; a second conductivity type second impurity region disposed inside the first impurity region and disposed on the first side surface of the first conversion device isolation layer; a second conductivity type third impurity region disposed inside the first impurity region and disposed on the second side surface of the first conversion device isolation layer; and a second conversion device isolation layer intersecting the first impurity region in a second direction perpendicular to the first direction.

The first conversion device isolation layer may bisect the first impurity region in the second direction. The second conversion device isolation layer may bisect the first impurity region in the first direction.

The first conversion device isolation layer and the second conversion device isolation layer may include an insulating material.

A horizontal width of the second conversion device isolation layer may be equal to a horizontal width of the first conversion device isolation layer.

In accordance with another aspect of the inventive concepts, an image sensor includes a substrate including a pixel region; a first conductivity type first impurity region disposed on the substrate and vertically overlapping the pixel region; a second conductivity type second impurity region extending in a first direction inside the first impurity region; a second conductivity type third impurity region extending in the first direction inside the first impurity region, and separated from the second impurity region in a second direction perpendicular to the first direction; a first conversion device isolation layer intersecting the first impurity region in the first direction between the second impurity region and the third impurity region; and a second conversion device isolation layer intersecting the first impurity region in the second direction.

A lowermost end of the second conversion device isolation layer may be higher than an uppermost end of the second impurity region and an uppermost end of the third impurity region.

A lowermost end of the first conversion device isolation layer may be lower than a lowermost end of the second conversion device isolation layer.

The image sensor may further include a pixel isolation layer disposed on the substrate and vertically overlapping a boundary of the pixel region. A horizontal width of the second conversion device isolation layer may be smaller than a horizontal width of the pixel isolation layer.

A horizontal width of the first conversion device isolation layer may be equal to a horizontal width of the pixel isolation layer.

In accordance with another aspect of the inventive concepts, an image sensor includes a substrate including pixel regions; photoelectric conversion devices disposed on the pixel regions of the substrate; and a conversion device isolation layer intersecting the photoelectric conversion devices in a cross-type. The conversion device isolation layer includes an insulating material.

### BRIEF DESCRIPTION OF THE DRAWINGS

The foregoing and other features and advantages of the inventive concepts will be apparent from the more particular description of example embodiments of the inventive concepts, as illustrated in the accompanying drawings in which like reference numerals denote the same respective parts throughout the different views. The drawings are not necessarily to scale, emphasis instead being placed upon illustrating the principles of the inventive concepts. In the drawings:

FIG. 1 illustrates a view showing an arrangement of pixel regions of an image sensor in accordance with some embodiments;

FIG. 2 illustrates an enlarged view of a portion U of FIG. 1;

FIG. 3A illustrates a cross sectional view taken along line I-I′ shown in FIG. 2;

FIG. 3B illustrates a cross sectional view taken along line II-II′ shown in FIG. 2;

FIGS. 4A and 4B illustrate cross-sectional views showing an image sensor in accordance with some embodiments;

FIG. 5 illustrates a view showing an image sensor in accordance with some embodiments;

FIG. 6A illustrates a cross sectional view taken along line III-III′ shown in FIG. 5;

FIG. 6B illustrates a cross sectional view taken along line IV-IV′ shown in FIG. 5;

FIGS. 7A and 7B illustrate cross-sectional views showing an image sensor in accordance with some embodiments;

FIGS. 8A and 8B illustrate cross-sectional views showing an image sensor in accordance with some embodiments;

FIGS. 9A and 9B illustrate cross-sectional views showing an image sensor in accordance with some embodiments;

FIGS. 10A and 10B illustrate cross-sectional views showing an image sensor in accordance with some embodiments;

FIG. 11 illustrates a view showing an image sensor in accordance with some embodiments;

FIG. 12A illustrates a cross sectional view taken along line V-V′ shown in FIG. 11;

FIG. 12B illustrates a cross sectional view taken along line VI-VI′ shown in FIG. 11;

FIGS. 13A and 13B illustrate views showing an image sensor in accordance with some embodiments;

FIGS. 14A and 14B illustrate views showing an image sensor in accordance with embodiments;

FIGS. 15A and 15B illustrate views showing an image sensor in accordance with some embodiments;

FIGS. 16A to 20A and 16B to 20B illustrate cross-sectional views of stages in a method of forming an image sensor in accordance with some embodiments;

FIGS. 21A, 21B, 22A, and 22B illustrate cross-sectional views of stages in a method of forming an image sensor in accordance with some embodiments;

FIGS. 23A to 25A and 23B to 25B illustrate cross-sectional views of stages in a method of forming an image sensor in accordance with some embodiments;

FIG. 26 illustrates a schematic view showing a camera module including the image sensor in accordance with some embodiments;

FIG. 27 illustrates a schematic view showing a mobile system including the image sensor in accordance with some embodiments; and

FIG. 28 illustrates a schematic view showing an electronic system including the image sensor in accordance with some embodiments.

### DETAILED DESCRIPTION OF EXAMPLE EMBODIMENTS

Particular structural and functional descriptions regarding embodiments of the inventive concepts set forth herein are simply provided to explain these embodiments. These embodiments are provided so that this disclosure is thorough and complete and fully conveys the inventive concepts to those skilled in the art. Thus, the inventive concepts may be accomplished in other various embodiments and should not be construed as limited to the embodiments set forth herein.

Like numerals refer to like elements throughout the specification. In the drawings, the lengths and thicknesses of layers and regions may be exaggerated for clarity. In addition, it will be understood that when a first element is referred to as being “on” a second element, the first element may be directly on the second element, or a third element may be interposed between the first element and the second element.

It will be understood that, although the terms including ordinal numbers such as “first,” “second,” etc. may be used herein to describe various elements, these terms are only used to distinguish one element from another. For example, a second element could be termed a first element without departing from the teachings of the present inventive concepts, and similarly a first element could be also termed a second element.

The terminology used herein to describe embodiments of the inventive concepts is not intended to limit the scope of the inventive concepts. The use of the singular form in the present document should not preclude the presence of more than one referent. In other words, elements of the inventive concepts referred to in the singular form may number one or more, unless the context clearly indicates otherwise. It will be further understood that the terms “comprises,” “comprising,” “includes,” and/or “including,” when used herein, specify the presence of stated elements, components, steps, operations, and/or devices, but do not preclude the presence or addition of one or more other elements, components, steps, operations, and/or devices.

Unless otherwise defined, all terms including technical and scientific terms used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

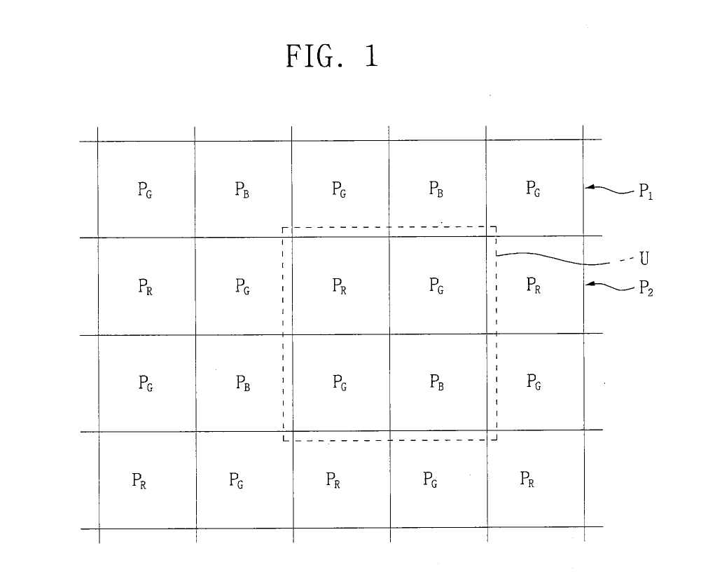

FIG. 1 illustrates a view showing a configuration of pixel regions of an image sensor in accordance with some embodiments.

Referring to FIG. 1, the image sensor in accordance with some embodiments includes a first row P1 having green pixel regions PG and blue pixel regions PB being alternately arranged and a second row P2 having red pixel regions PR and green pixel regions PG being alternately arranged. The first row P1 and the second row P2 may be repeatedly arranged in each other. The green pixel regions PG of the first row P1 and the green pixel regions PG of the second row P2 may be arranged to face each other along a diagonal direction. For example, the green pixel regions PG may be arranged in a zigzag shape. The blue pixel regions PB of the first row P1 may be arranged to be offset from the red pixel regions PR of the second row P2.

In the image sensor in accordance with embodiments, the green pixel regions PG may be arranged in a zigzag shape, and each of the blue pixel regions PB or the red pixel regions PR may be disposed between the green pixel regions PG in each row. However, in an image sensor according to some embodiment of the inventive concepts, a first row P1 having white pixel regions PW and blue pixel regions PB being alternately arranged and a second row P2 having red pixel regions PR and white pixel regions PW being alternately arranged may be repeatedly arranged in each other. Further, in an image sensor according to some embodiment of the inventive concepts, a red pixel region PR, a white pixel region PW, and a blue pixel region PB which are alternately disposed in a row direction may be arranged so that same colored pixel regions are not in contiguity with each other in a column direction.

Each area of the green pixel regions PG may be the same as each area of the blue pixel regions PB. Each area of the blue pixel regions PB may be the same as each area of the red pixel regions PR. The green pixel region PG and the blue pixel region PB of the first row P1, and the red pixel region PR and the green pixel region PG of the second row P2 may constitute a unit pixel U.

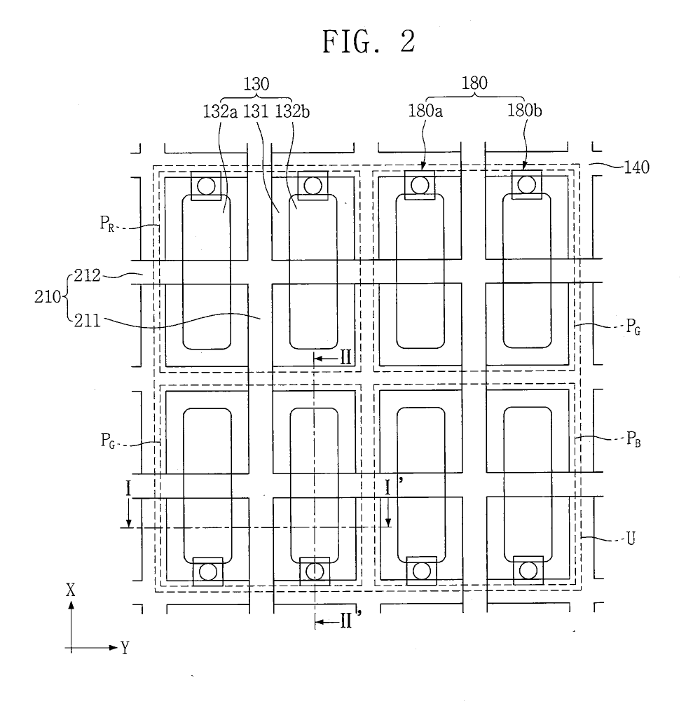

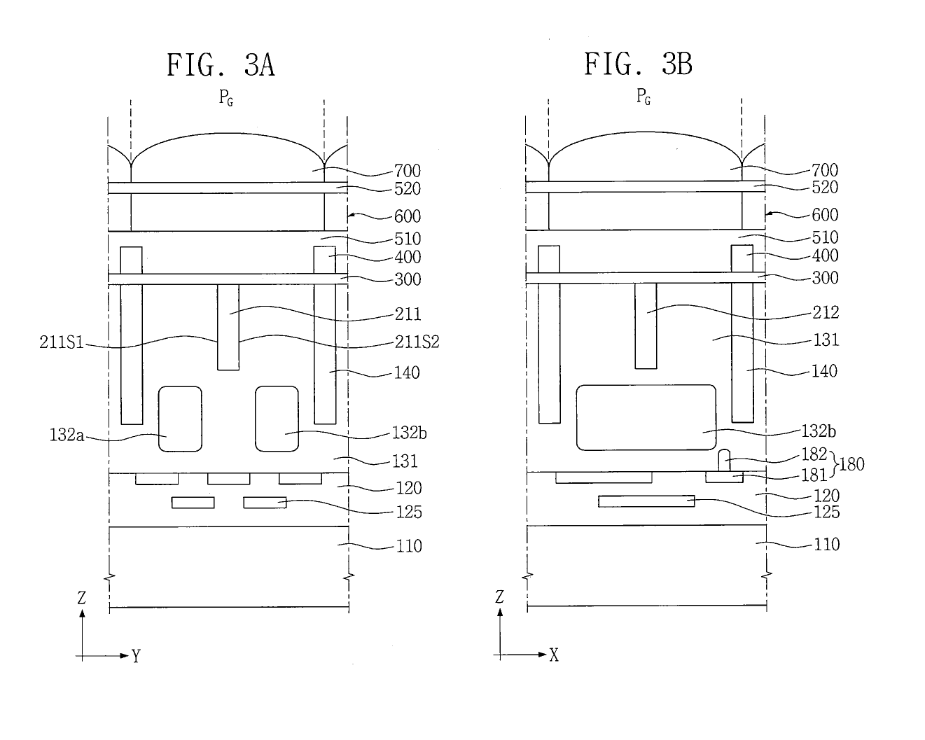

FIG. 2 illustrates a view showing the unit pixel U of the image sensor in accordance with some embodiments. FIG. 3A illustrates a cross sectional view taken along line I-I′ shown in FIG. 2. FIG. 3B illustrates a cross sectional view taken along line II-II′ shown in FIG. 2.

Referring to FIGS. 2, 3A, and 3B, the image sensor in accordance with some embodiments may include a substrate 110, an interconnection layer 120, a photoelectric conversion device 130, a pixel isolation layer 140, a conversion device isolation layer 210, a buffer layer 300, a metal grid 400, a lower planarization layer 510, a color filter 600, and a microlens 700.

The substrate 110 may include a semiconductor substrate, a glass substrate, and a metal substrate. The substrate 110 may include a green pixel region PG, a blue pixel region PB and a red pixel region PR.

The interconnection layer 120 may be disposed on the substrate 110. The substrate 110 may be attached to the interconnection layer 120. The interconnection layer 120 may include an insulating material. For example, the interconnection layer 120 may include silicon oxide and/or silicon nitride.

Internal circuit line 125 may be disposed inside the interconnection layer 120. For example, the interconnection layer 120 may be a multilayer structure.

The photoelectric conversion device 130 may absorb incident light and generate/accumulate electric charge corresponding to absorbed light. The photoelectric conversion device 130 may be disposed on the interconnection layer 120. The photoelectric conversion device 130 may vertically overlap the pixel regions PR, PB, and PR of the substrate 110 in a vertical direction. For example, the photoelectric conversion device 130 may include green photoelectric conversion devices vertically overlapping the green pixel regions PG, blue photoelectric conversion devices vertically overlapping the blue pixel regions PB and red photoelectric conversion devices vertically overlapping the red pixel regions PR.

Each of the photoelectric conversion devices 130 may include a first impurity region 131, a second impurity region 132a, and a third impurity region 132b. The first impurity region 131 may include a first conductivity type dopant. The second impurity region 132a and the third impurity region 132b may include a second conductivity type dopant. For example, the first impurity region 131 may include a p-type dopant, the second impurity region 132a and the third impurity region 132b may include an n-type dopant. The second impurity region 132a and the third impurity region 132b may be disposed inside the first impurity region 131. The first impurity region 131 may surround the second impurity region 132a and the third impurity region 132b. For example, the photoelectric conversion device 130 may include a photodiode.

The second impurity region 132a may extend in a first direction X in the first impurity region 131. The third impurity region 132b may extend in the first direction X in the first impurity region 131. The third impurity region 132b may be separated from the second impurity region 132a in a second direction Y perpendicular to the first direction X. For example, the third impurity region 132b may be parallel to the second impurity region 132a.

A shape of the third impurity region 132b may be identical to a shape of the second impurity region 132a. For example, a length of the third impurity region 132b in the first direction may be equal to that of the second impurity region 132a in the first direction. A length of the third impurity region 132b in the second direction may be equal to that of the second impurity region 132a in the second direction. A level of a lowermost end of the third impurity region 132b may be equal to that of the second impurity region 132a. A level of an uppermost end of the third impurity region 132b may be equal to that of the second impurity region 132a.

The pixel isolation layer 140 may be disposed on the substrate 110. The pixel isolation layer 140 may vertically overlap boundaries between the pixel regions PR, PB, and PR. For example, the photoelectric conversion devices 130 may be surrounded by the pixel isolation layer 140.

A level of an upper surface of the pixel isolation layer 140 may be equal to that of the photoelectric conversion devices 130. The level of the upper surface of the pixel isolation layer 140 may be equal to that of the first impurity region 131. An uppermost end of the pixel isolation layer 140 may be higher than an uppermost end of the second impurity region 132a and an uppermost end of the third impurity region 132b.

A vertical length of the pixel isolation layer 140 may be less than that of the photoelectric conversion devices 130. A lowermost end of the pixel isolation layer 140 may be higher than that of the first impurity region 131. A lowermost end of the pixel isolation layer 140 may be lower than the uppermost end of the second impurity region 132a and the uppermost end of the third impurity region 132b. For example, a lowermost end of the pixel isolation layer 140 may be higher than that of the second impurity region 132a and that of the third impurity region 132b.

The pixel isolation layer 140 may include an insulating material. For example, the pixel isolation layer 140 may include silicon oxide or silicon nitride.

The image sensor in accordance with embodiments may further include a transfer gate 180 disposed in each pixel region PR, PB, and PR. Each of the transfer gates 180 may be disposed between the interconnection layer 120 and the corresponding photoelectric conversion device 130. For example, each of the transfer gates 180 may include a first region 181 disposed inside the interconnection layer 120 and a second region 182 disposed inside the first impurity region 131.

In the image sensor in accordance with embodiments, the transfer gate 180 may include a region protruding into the photoelectric conversion device 130. However, in an image sensor according to some embodiment of the inventive concepts, the transfer gate 180 may be formed in a different shape.

Each of the transfer gates 180 may include a first transfer gate 180a and a second transfer gate 180b. The first transfer gate 180a may be disposed between the second impurity region 132a and the pixel isolation layer 140. The second transfer gate 180b may be disposed between the third impurity region 132b and the pixel isolation layer 140.

The conversion device isolation layer 210 may be disposed inside the photoelectric conversion devices 130. For example, the conversion device isolation layer 210 may be disposed inside each of the first impurity regions 131 of the photoelectric conversion devices 130.

An upper surface of the conversion device isolation layer 210 may be a cross-type. The conversion device isolation layer 210 may intersect the first impurity region 131 in the first direction X and in the second direction Y.

The conversion device isolation layers 210 intersecting the adjacent photoelectric conversion device 130 may be connected to each other. For example, the conversion device isolation layer 210 may intersect the pixel isolation layer 140.

The conversion device isolation layer 210 may include a first conversion device isolation layer 211 and a second conversion device isolation layer 212.

The first conversion device isolation layer 211 may extend in the first direction X. Each of the photoelectric conversion devices 130 may be divided into the first impurity region 131 positioned on the second impurity region 132a and the first impurity region 131 positioned on the third impurity region 132b by the first conversion device isolation layer 211. For example, the first conversion device isolation layer 211 may intersect the first impurity region 131 in the first direction X between the second impurity region 132a and the third impurity region 132b.

The first conversion device isolation layer 211 may include a first side surface 211S1 and a second side surface 211S2. The second side surface 211S2 of the first conversion device isolation layer 211 may be opposite the first side surface 211S1 of the first conversion device isolation layer 211. For example, the second impurity region 132a may be disposed in a direction of the first side surface 211S1 of the first conversion device isolation layer 211 and the third impurity region 132b may be disposed in a direction of the second side surface 211S2 of the first conversion device isolation layer 211.

The first conversion device isolation layer 211 may bisect the first impurity region 131 in the second direction Y. The third impurity region 132b and the second impurity region 132a may be symmetrical based on the first conversion device isolation layer 211.

A level of an upper surface of the first conversion device isolation layer 211 may be equal to that of the pixel isolation layer 140. The level of the upper surface of the first conversion device isolation layer 211 may be equal to that of the first impurity region 131. An uppermost end of the first conversion device isolation layer 211 may be in a higher level than those of the second impurity region 132a and the third impurity region 132b.

A vertical length of the first conversion device isolation layer 211 may be less than that of the pixel isolation layer 140. A lowermost end of the first conversion device isolation layer 211 may be in a higher level than that of the pixel isolation layer 140. The lowermost end of the first conversion device isolation layer 211 may be in a higher level than the uppermost end of the second impurity region 132a and the uppermost end of the third impurity region 132b.

A horizontal width of the of first conversion device isolation layer 211 may be less than a distance in the second direction Y between the second impurity region 132a and the third impurity region 132b. For example, the horizontal width of the first conversion device isolation layer 211 may be equal to that of the pixel isolation layer 140.

The first conversion device isolation layer 211 may include an insulating material. For example, the first conversion device isolation layer 211 may include silicon oxide.

The second conversion device isolation layer 212 may extend in the second direction Y. The second conversion device isolation layer 212 may intersect the first impurity region 131 in the second direction Y. The second conversion device isolation layer 212 may cross the first conversion device isolation layer 211.

A level of an upper surface of the second conversion device isolation layer 212 may be equal to that of the first conversion device isolation layer 211. The level of the upper surface of the second conversion device isolation layer 212 may be equal to that of the first impurity region 131. An uppermost end of the second conversion device isolation layer 212 may be in a higher level than those of the second impurity region 132a and the third impurity region 132b.

A vertical length of the second conversion device isolation layer 212 may be equal to that of the first conversion device isolation layer 211. A lowermost end of the second conversion device isolation layer 212 may be in a higher level than that of the pixel isolation layer 140. The lowermost end of the second conversion device isolation layer 212 may be in a higher level than the uppermost end of the second impurity region 132a and the uppermost end of the third impurity region 132b.

The second conversion device isolation layer 212 may cross the second impurity region 132a and the third impurity region 132b. The second conversion device isolation layer 212 may intersect the first impurity region 131 in the second direction Y over the second impurity region 132a and the third impurity region 132b.

The second conversion device isolation layer 212 may bisect the first impurity region 131 in the first direction X. For example, the second impurity region 132a may have a symmetrical shape based on the second conversion device isolation layer 212. The second conversion device isolation layer 212 may vertically overlap a region that bisects the third impurity region 132b in the first direction X.

A horizontal width of the second conversion device isolation layer 212 may be equal to that of the first conversion device isolation layer 211. For example, a horizontal width of the second conversion device isolation layer 212 may be the same as that of the pixel isolation layer 140.

The second conversion device isolation layer 212 may include an insulating material. For example, the second conversion device isolation layer 212 may include silicon oxide. The second conversion device isolation layer 212 may include the same material as the first conversion device isolation layer 211. For example, the second conversion device isolation layer 212 may be materially continuous with the first conversion device isolation layer 211.

In the image sensor in accordance with embodiments, photoelectric conversion devices 130 intersecting the conversion device isolation layer 210 may include a first conversion device isolation layer 211 extending in the first direction X and a second conversion device isolation layer 212 extending in the second direction Y. The directivity of light diffused and reflected by the second conversion device isolation layer 212 may offset that of the light diffused and reflected by the first conversion device isolation layer 211. Accordingly, in the image sensor in accordance with embodiments, the light diffused and reflected by the conversion device isolation layer 210 may be uniformly applied to adjacent pixel regions. Therefore, in the image sensor in accordance with embodiments, cross-talk between pixel regions PR, PB, and PR adjacent in the first direction X may be equal to that of between pixel regions PR, PB, and PR adjacent in the second direction Y.

In the image sensor in accordance with embodiments, a first conversion device isolation layer 211 may bisect a first impurity region 131 in the second direction Y, and a second conversion device isolation layer 212 may bisect the first impurity region 131 in the first direction X. Therefore, in the image sensor in accordance with embodiments, cross-talk caused by the first conversion device isolation layer 211 between pixel regions PR, PB, and PR adjacent in the second direction Y and cross-talk caused by the second conversion device isolation layer 212 between pixel regions PR, PB, and PR adjacent in the first direction X may be uniform.

The buffer layer 300 may be disposed on the photoelectric conversion device 130. The buffer layer 300 may be disposed on the pixel isolation layer 140 and the conversion device isolation layer 210. An upper surface of the photoelectric conversion device 130 may be covered with the buffer layer 300. The first impurity region 131 of each of the photoelectric conversion devices 130 may be in direct contact with the buffer layer 300.

The buffer layer 300 may include an insulating material. For example, the buffer layer 300 may include hafnium oxide (HfO).

The metal grid 400 may be disposed on the buffer layer 300. The metal grid 400 may be aligned in a vertical direction with boundaries between the pixel regions PR, PB, and PR. The metal grid 400 may be disposed on the pixel isolation layer 140.

The metal grid 400 may include a metal. For example, the metal grid 400 may include aluminum (Al), chromium (Cr), molybdenum (Mo), titanium (Ti) or tungsten (W).

The lower planarization layer 510 may be disposed on the buffer layer 300. The lower planarization layer 510 may be disposed on the metal grid 400. The metal grid 400 may be completely covered by the lower planarization layer 510. An upper surface of the lower planarization layer 510 may be in a higher level than an uppermost end of the metal grid 400.

The lower planarization layer 510 may include an insulating material. For example, the lower planarization layer 510 may include silicon oxide.

The color filter 600 may be disposed on the lower planarization layer 510. The color filter 600 may vertically overlap the photoelectric conversion device 130. Boundaries between the color filters 600 may vertically overlap the pixel isolation layer 140. The color filter 600 may vertically overlap the pixel regions PR, PB, and PR. For example, boundaries between the color filters 600 may vertically overlap boundaries between the pixel regions PR, PB, and PR. For example, the color filter 600 may include green color filter vertically overlapping the green pixel region PG, blue color filter vertically overlapping the blue pixel region PB and red color filter vertically overlapping the red pixel region PR.

The microlens 700 may be respectively disposed on the color filter 600. The microlens 700 may vertically overlap the color filter 600. For example, boundaries between the microlenses 700 may vertically overlap boundaries between the color filters 600. The microlens 700 may vertically overlap the pixel regions PR, PB, and PR.

The image sensor in accordance with embodiments may further include an upper planarization layer 520 interposed between the color filter 600 and the microlens 700. The upper planarization layer 520 may include an insulating material. For example, the upper planarization layer 520 may include silicon oxide.

The image sensor in accordance with embodiments may include the conversion device isolation layer 210 intersecting the photoelectric conversion device 130 in a cross-type. Therefore, in the image sensor in accordance with embodiments, the light diffused and reflected by the conversion device isolation layer 210 may be uniformly applied to a corresponding one of adjacent pixel regions PR, PB, and PR. That is, in the image sensor in accordance with embodiments, cross-talk caused by the conversion device isolation layer 210 between adjacent pixel regions PR, PB, and PR may be uniform. Thus, in the image sensor in accordance with embodiments, a color gamut can be improved.

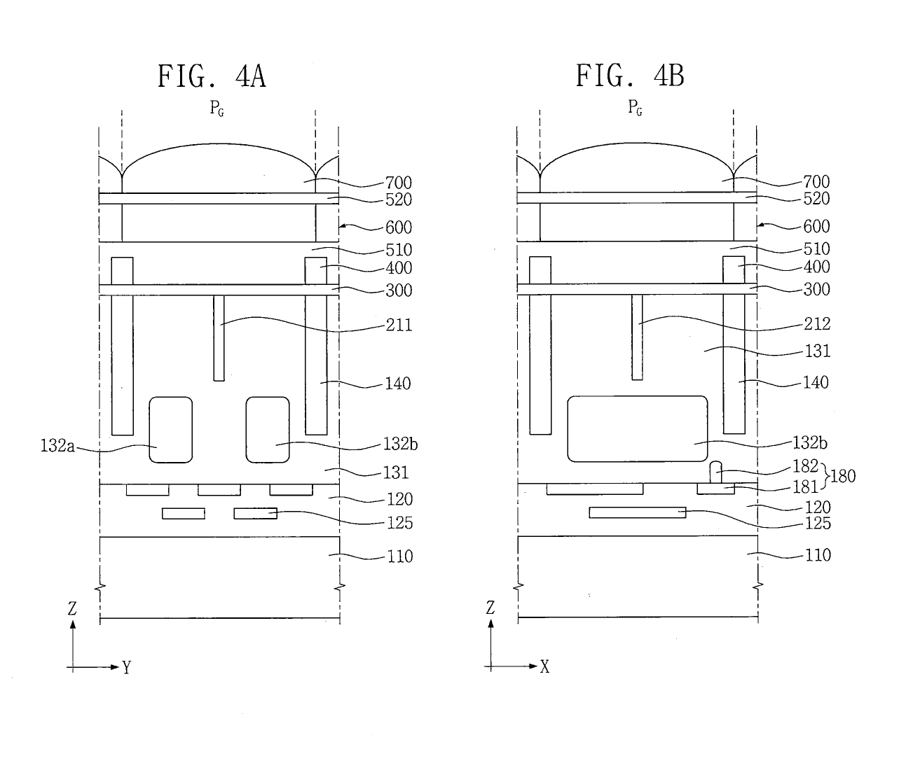

In the image sensor in accordance with embodiments, a horizontal width of the conversion device isolation layer 210 may be equal to that of the pixel isolation layer 140. However, as shown FIGS. 4A and 4B, in the image sensor according to some embodiment of the inventive concepts, a horizontal width of the conversion device isolation layer 210 may be less than that of the pixel isolation layer 140.

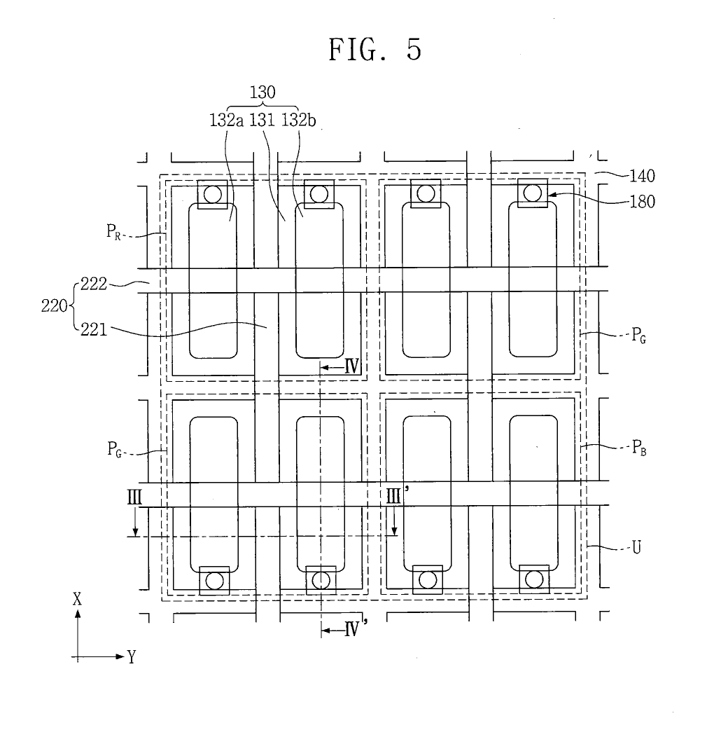

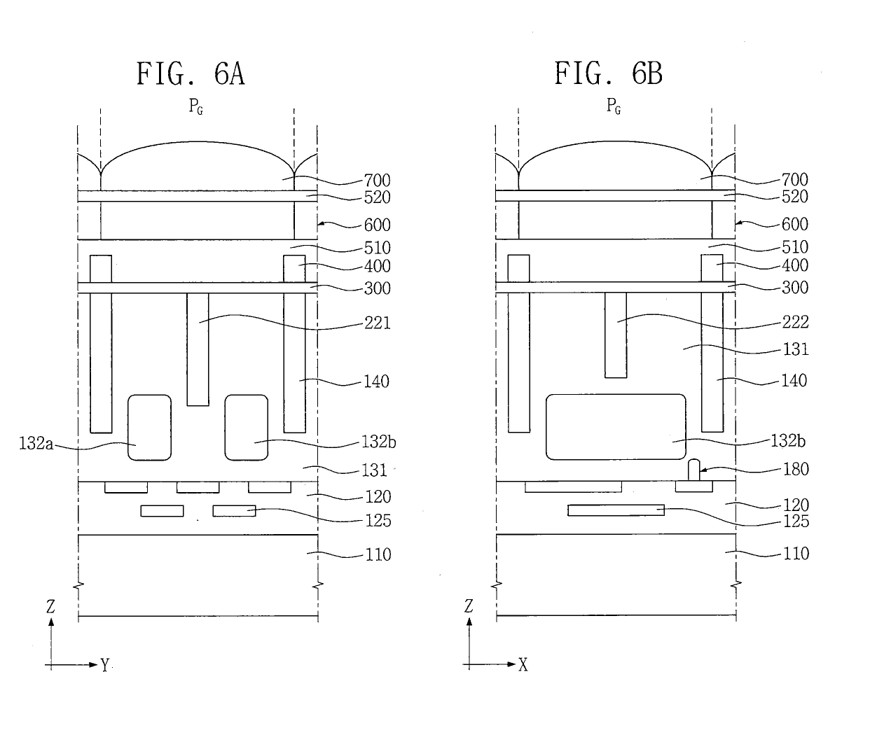

FIG. 5 illustrates a view showing an image sensor in accordance with embodiments. FIG. 6A illustrates a cross sectional view taken along line III-III′ shown in FIG. 5. FIG. 6B illustrates a cross sectional view taken along line IV-IV′ shown in FIG. 5.

Referring to FIGS. 5, 6A, and 6B, the image sensor in accordance with embodiments may include a substrate 110 including pixel regions PR, PB, and PR, an interconnection layer 120, a photoelectric conversion device 130, pixel isolation layer 140, a conversion device isolation layer 220, a buffer layer 300, a metal grid 400, a lower planarization layer 510, color filters 600, an upper planarization layer 520, and a microlens 700. The image sensor in accordance with embodiments may further include transfer gate 180.

Each of the photoelectric conversion devices 130 may include a first conductivity type first impurity region 131, a second conductivity type second impurity region 132a, and a second conductivity type third impurity region 132b. The second impurity region 132a and the third impurity region 132b may extend in a first direction X. The third impurity region 132b may be separated from the second impurity region 132a in a second direction Y perpendicular to the first direction X.

The conversion device isolation layer 220 may include a first conversion device isolation layer 221 and a second conversion device isolation layer 222. The first conversion device isolation layer 221 may intersect the photoelectric conversion devices 130 in the first direction X. The second conversion device isolation layer 222 may intersect the photoelectric conversion devices 130 in the second direction Y. A lowermost end of the second conversion device isolation layer 222 may be in a higher level than an uppermost end of the second impurity region 132a and an uppermost end of the third impurity region 132b.

The second conversion device isolation layer 222 may intersect the first conversion device isolation layer 221. For example, the first conversion device isolation layer 221 may be bisected in a pixel region PR, PB, and PR by the second conversion device isolation layer 222.

A horizontal width of the second conversion device isolation layer 222 may be equal to that of the first conversion device isolation layer 221. A horizontal width of the first conversion device isolation layer 221 may be equal to that of the pixel isolation layer 140.

A vertical length of the first conversion device isolation layer 221 may be greater than that of the second conversion device isolation layer 222. A lowermost end of the first conversion device isolation layer 221 may be in a lower level than that of the second conversion device isolation layer 222. For example, a lowermost end of the first conversion device isolation layer 221 may be in a lower level than an uppermost end of the second impurity region 132a and an uppermost end of the third impurity region 132b.

A vertical length of the first conversion device isolation layer 221 may be less than that of the pixel isolation layer 140. For example, a lowermost end of the first conversion device isolation layer 221 may be in a higher level than that of the pixel isolation layer 140.

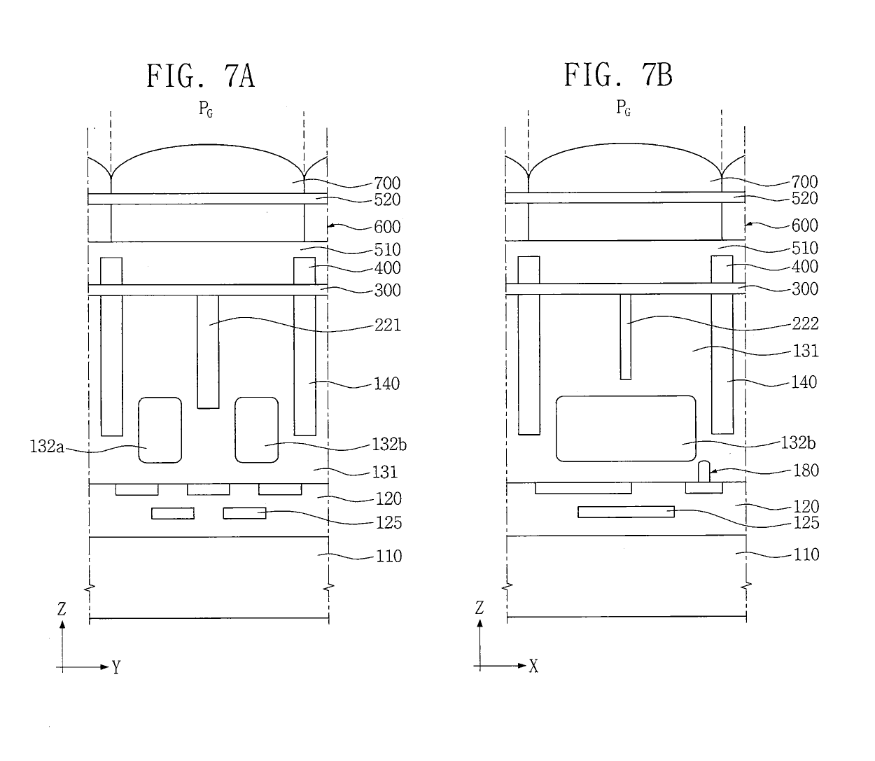

In the image sensor in accordance with embodiments, a horizontal width of a second conversion device isolation layer 222 may be equal to that of a first conversion device isolation layer 221. However, as shown in FIGS. 7A and 7B, in the image sensor according to some embodiment of the inventive concepts, a horizontal width of a second conversion device isolation layer 222 may be less than that of a first conversion device isolation layer 221.

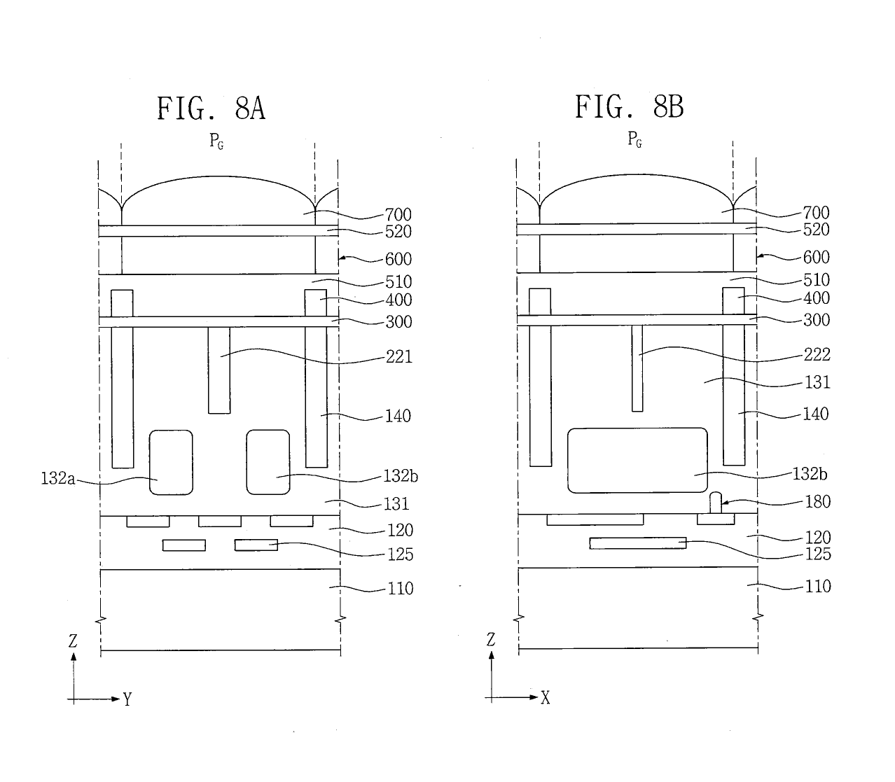

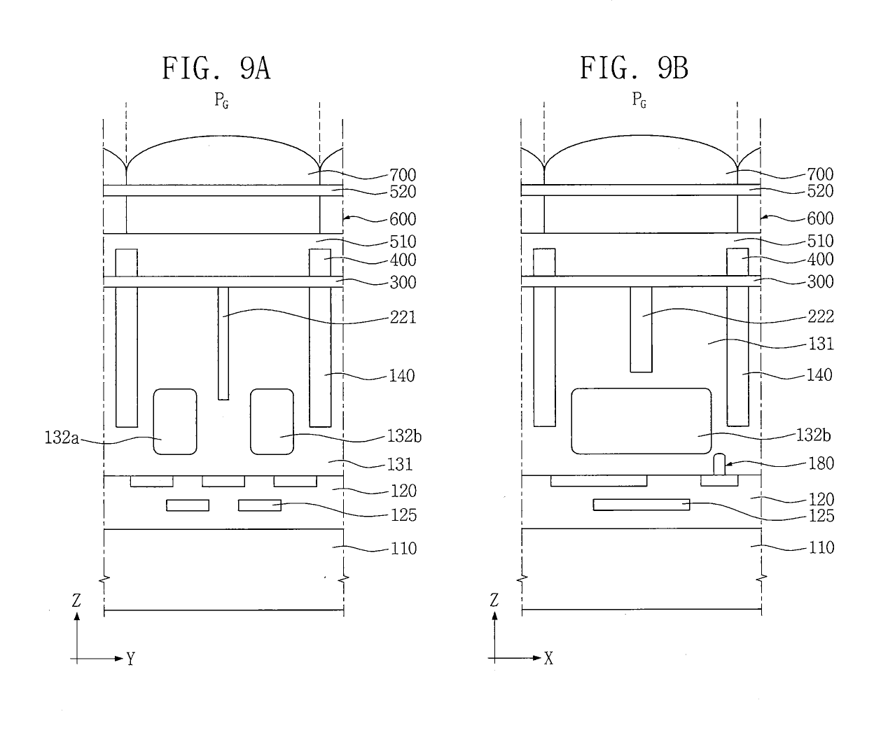

In the image sensor in accordance with embodiments, a vertical length of a first conversion device isolation layer 221 may be greater than that of a second conversion device isolation layer 222, and the horizontal width of the second conversion device isolation layer 222 may be equal to that of the first conversion device isolation layer 221. However, as shown in FIGS. 8A and 8B, in an image sensor according to some embodiment of the inventive concepts, a vertical length of a first conversion device isolation layer 221 may be equal to that of a second conversion device isolation layer 222, and a horizontal width of the second conversion device isolation layer 222 may be less than that of the first conversion device isolation layer 221. As shown in FIGS. 9A and 9B, in the image sensor according to some embodiment of the inventive concepts, a vertical length of a first conversion device isolation layer 221 may be greater than that of a second conversion device isolation layer 222, and a horizontal width of the first conversion device isolation layer 221 may be less than that of the second conversion device isolation layer 222.

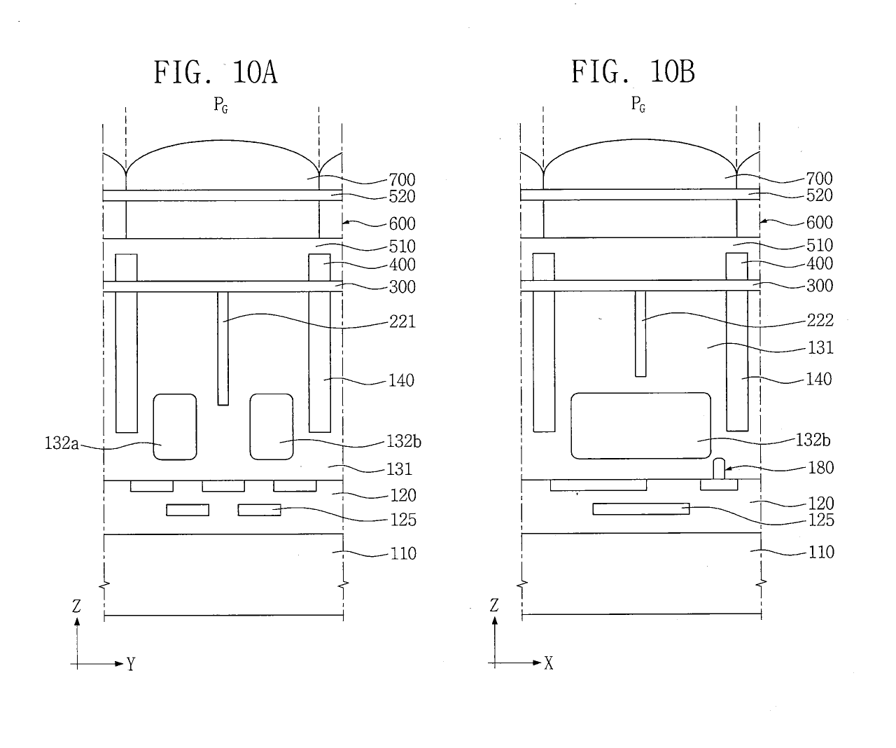

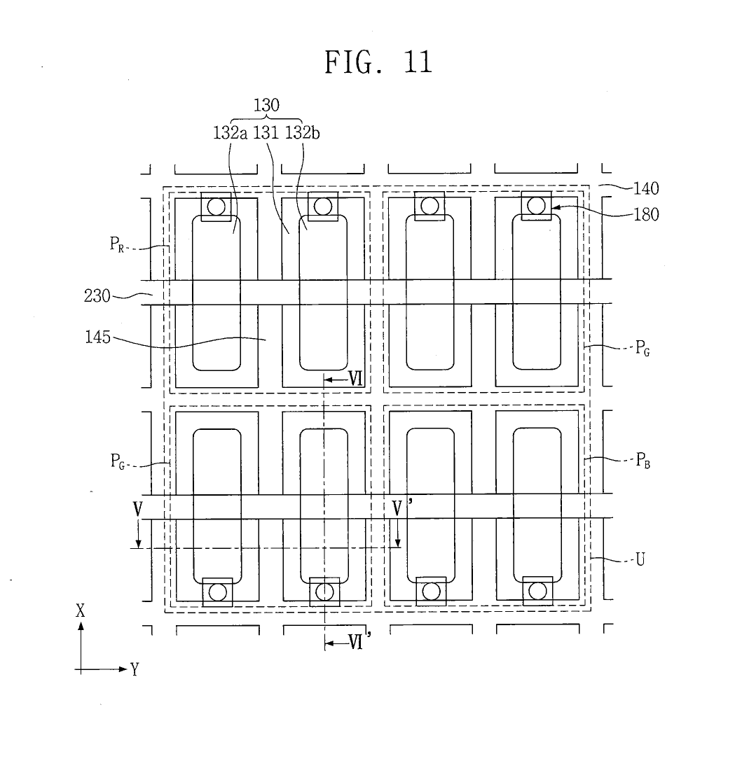

In the image sensor in accordance with embodiments, a horizontal width of a first conversion device isolation layer 221 and a horizontal width of a second conversion device isolation layer 222 may be equal to that of a pixel isolation layer 140. However, as shown in FIGS. 10A and 10B, in an image sensor according to some embodiment of the inventive concepts, a horizontal width of a first conversion device isolation layer 221 and a horizontal width of a second conversion device isolation layer 222 may be less than that of a pixel isolation layer 140.

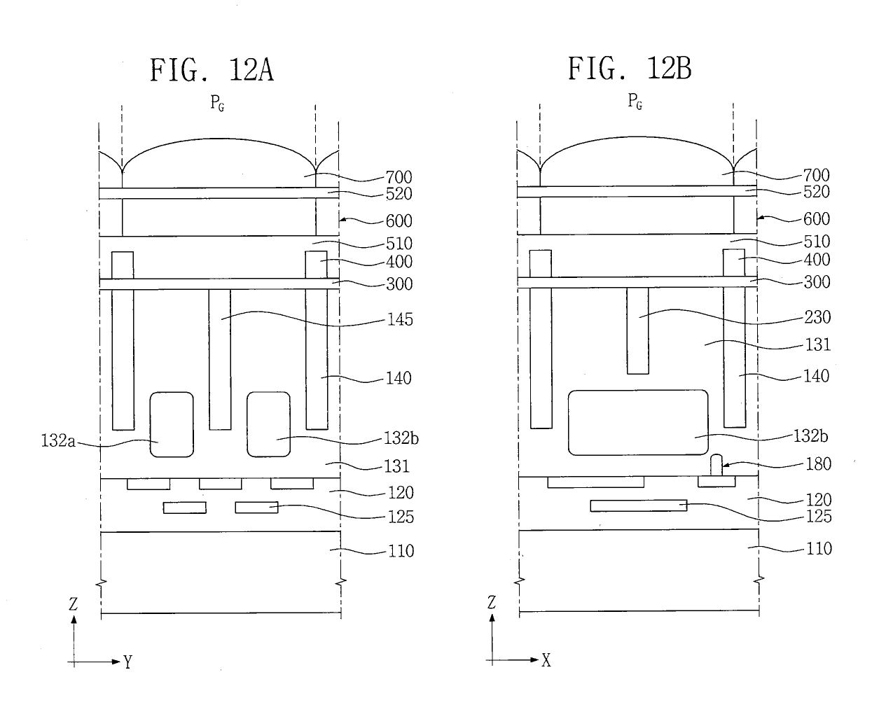

FIG. 11 illustrates a view showing an image sensor in accordance with embodiments. FIG. 12A illustrates a cross sectional view taken along line V-V′ shown in FIG. 11. FIG. 12B illustrates a cross sectional view taken along line VI-VI′ shown in FIG. 11.

Referring to FIGS. 11, 12A and 12B, the image sensor according to the embodiment of the inventive concepts may include a substrate 110 including pixel regions PR, PB, and PR, an interconnection layer 120, a photoelectric conversion device 130, a pixel isolation layer 140, an X-axis conversion device isolation layer 145, a transfer gate 180, a Y-axis conversion device isolation layer 230, a buffer layer 300, metal grid 400, a lower planarization layer 510, a color filter 600, an upper planarization layer 520, and a microlens 700.

The photoelectric conversion devices 130 may each include a first impurity region 131 having a first conductivity type, a second impurity region 132a having a second conductivity type, and a third impurity region 132b having the second conductivity type.

The X-axis conversion device isolation layer 145 may intersect the photoelectric conversion device 130 in a first direction X. A level of an upper surface of the X-axis conversion device isolation layer 145 may be the same as that of the first impurity region 131. A vertical length of the X-axis conversion device isolation layer 145 may be the same as that of the pixel isolation layer 140. A lowermost end of the X-axis conversion device isolation layer 145 may be the same as that of the pixel isolation layer 140. For example, a lowermost end of the X-axis conversion device isolation layer 145 may be disposed between a side surface of the second impurity region 132a and a side surface of the third impurity region 132b.

A horizontal width of the X-axis conversion device isolation layer 145 may be the same as that of the pixel isolation layer 140. The X-axis conversion device isolation layer 145 may include the same material as the pixel isolation layer 140. For example, the X-axis conversion device isolation layer 145 may be materially continuous with the pixel isolation layer 140.

The Y-axis conversion device isolation layer 230 may intersect the photoelectric conversion device 130 in the second direction Y perpendicular to the first direction X. For example, the Y-axis conversion device isolation layer 230 may intersect the pixel isolation layer 140 and the X-axis conversion device isolation layer 145.

A level of an upper surface of the Y-axis conversion device isolation layer 230 may be the same as that of the X-axis conversion device isolation layer 145. A vertical length of the Y-axis conversion device isolation layer 230 may be less than that of the pixel isolation layer 140. A vertical length of the Y-axis conversion device isolation layer 230 may be less than that of the X-axis conversion device isolation layer 145. For example, a lowermost end of the X-axis conversion device isolation layer 145 may be in a lower level than that of the Y-axis conversion device isolation layer 230. For example, a lowermost end of the Y-axis conversion device isolation layer 230 may be in a higher level than an uppermost end of the second impurity region 132a and an uppermost end of the third impurity region 132b.

A horizontal width of the Y-axis conversion device isolation layer 230 may be equal to that of the X-axis conversion device isolation layer 145. A horizontal width of the Y-axis conversion device isolation layer 230 may be equal to that of the pixel isolation layer 140.

The Y-axis conversion device isolation layer 230 may include an insulating material. For example, the Y-axis conversion device isolation layer 230 may include silicon oxide. The Y-axis conversion device isolation layer 230 may include a different insulating material from the X-axis conversion device isolation layer 145. The Y-axis conversion device isolation layer 230 may include a different insulating material from the pixel isolation layer 140.

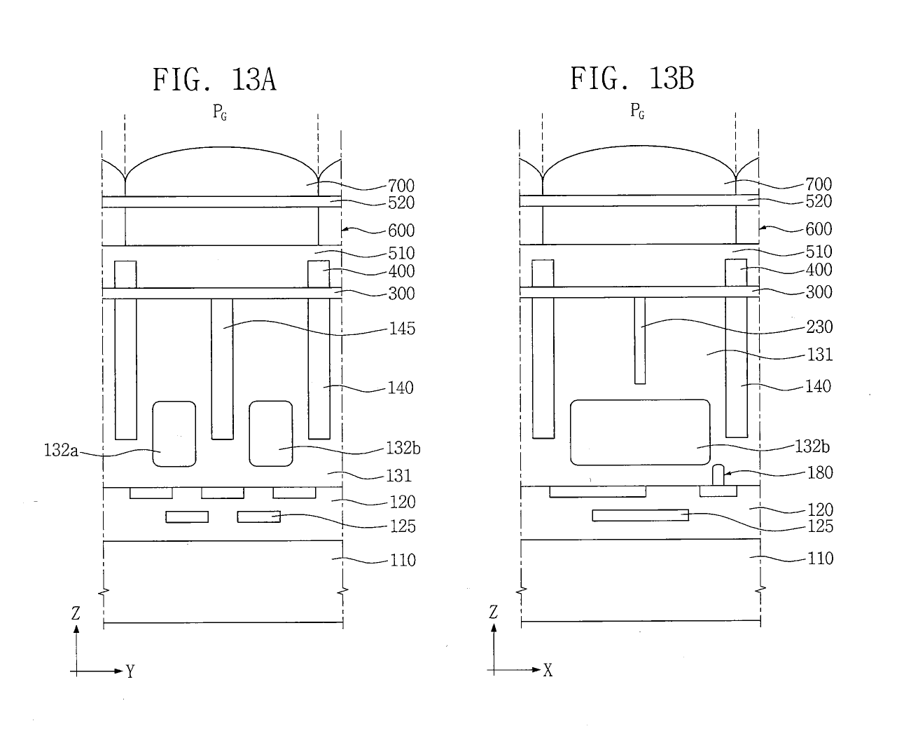

In the image sensor in accordance with embodiments, the horizontal width of the Y-axis the conversion device isolation layer 230 may be equal to that of the X-axis the conversion device isolation layer 145. However, as shown in FIGS. 13A and 13B, in an image sensor according to some embodiment of the inventive concepts, a horizontal width of a Y-axis conversion device isolation layer 230 may be less than that of an X-axis conversion device isolation layer 145.

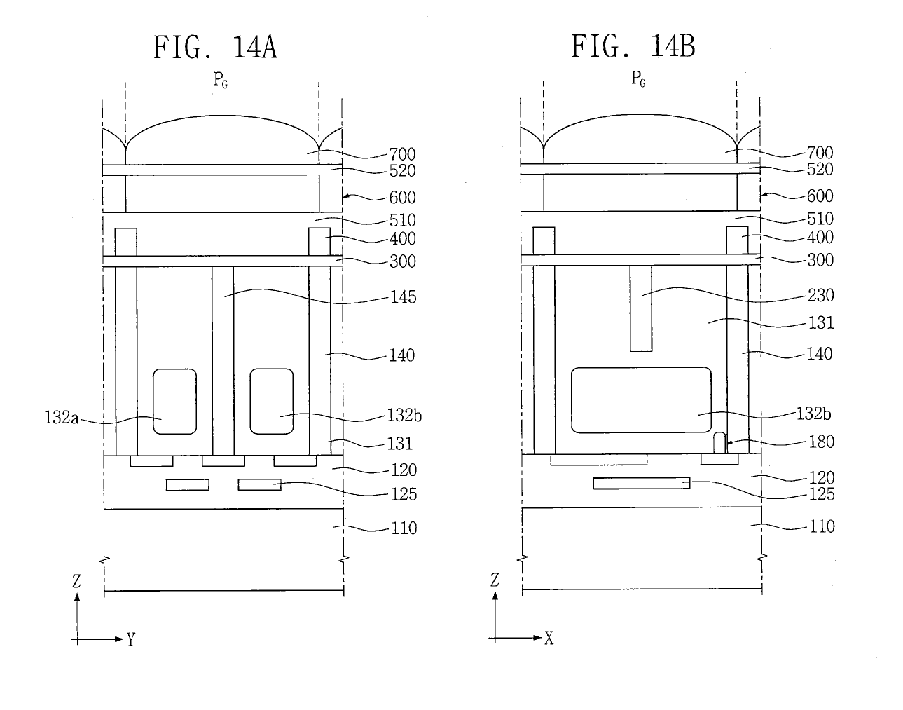

In the image sensor in accordance with embodiments, a vertical length of the pixel isolation layer 140 and a vertical length of the X-axis conversion device isolation layer 145 may be less than that of a first impurity region 131. However, as shown in FIGS. 14A and 14B, in an image sensor according to some embodiment of the inventive concepts, a vertical length of a pixel isolation layer 140 and a vertical length of the X-axis conversion device isolation layer 145 may be equal to that of a first impurity region 131.

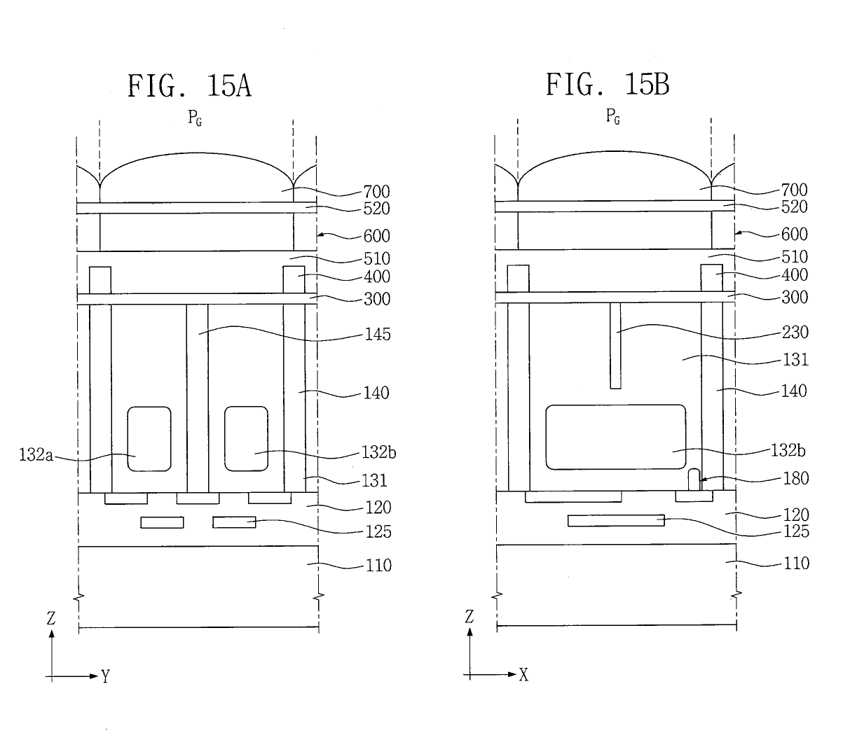

In the image sensor in accordance with embodiments, the X-axis conversion device isolation layer 145 having the same horizontal width as the Y-axis conversion device isolation layer 230 may have a smaller vertical length than the first impurity region 131. However, as shown in FIGS. 15A and 15B, in an image sensor according to some embodiment of the inventive concepts, a horizontal width of the Y-axis conversion device isolation layer 230 may be less than that of the X-axis conversion device isolation layer 145 having the same vertical length as a first impurity region 131.

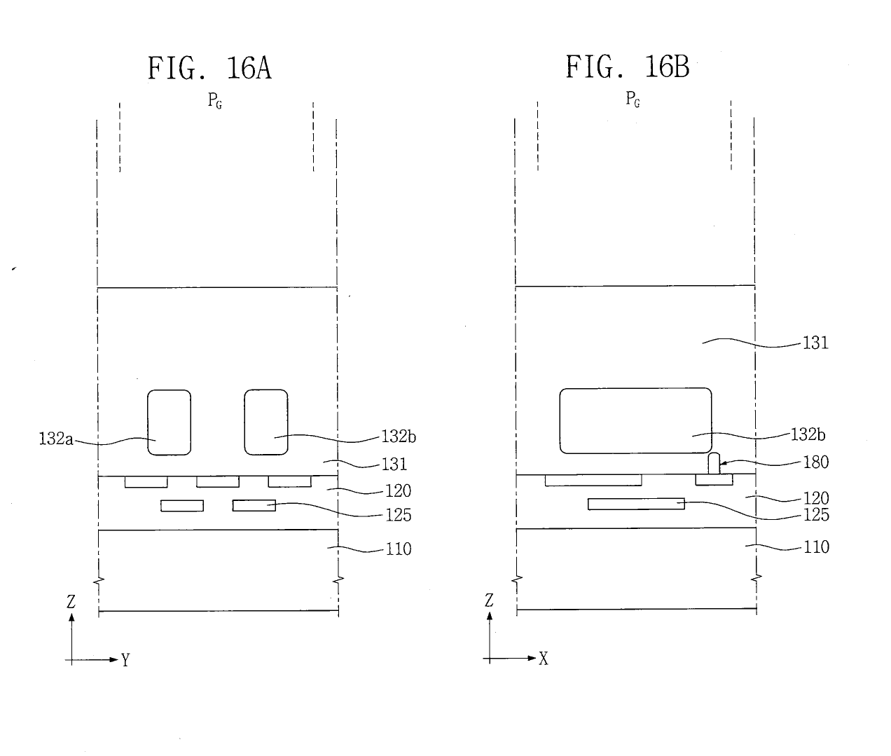

FIGS. 16A to 20A and 16B to 20B illustrate cross-sectional views of stages in a method of forming an image sensor in accordance with embodiments.

The method of forming the image sensor in accordance with embodiments will be described with referring to FIGS. 1, 2, 3A, 3B, 16A to 20A, and 16B to 20B. Referring to FIGS. 1, 16A, and 16B, the method of forming the image sensor in accordance with embodiments may include a process of preparing a substrate 110 on which an interconnection layer 120 and photoelectric conversion devices 130 are formed.

The process of preparing the substrate 110 may include a process of forming photoelectric conversion device 130, a process of forming an interconnection layer 120 under a lower surface of the photoelectric conversion device 130 and a process of forming the substrate 110 including pixel regions PR, PB, and PR on a lower surface of the interconnection layer 120. The pixel regions PR, PB, and PR may include green pixel regions PG, blue pixel regions PB and red pixel regions PR, respectively. The process of preparing the substrate 110 may further include a process of performing an etch-back process on an upper surface of the photoelectric conversion device 130.

The process of forming the photoelectric conversion device 130 may include a process of forming second conductivity type second impurity regions 132a and second conductivity type third impurity regions 132b in a first conductivity type first impurity region 131. The process of forming the second impurity regions 132a and the third impurity region 132b may include a process of ion implanting the second conductivity type dopants into the first impurity region 131 having the first conductivity type dopants.

The process of forming the interconnection layer 120 may include a process of forming internal interconnection circuit layers 125 under a lower surface of the photoelectric conversion device 130. The process of forming the interconnection layer 120 may further include a process of forming transfer gates 180 on a lower surface of the photoelectric conversion device 130.

The process of forming the substrate 110 may include a process of attaching the substrate 110 including pixel regions PR, PB, and PR on a lower surface of the interconnection layer 120. One second impurity region 132a and one third impurity region 132b may be disposed in each of the pixel regions PR, PB, and PR of the substrate 110.

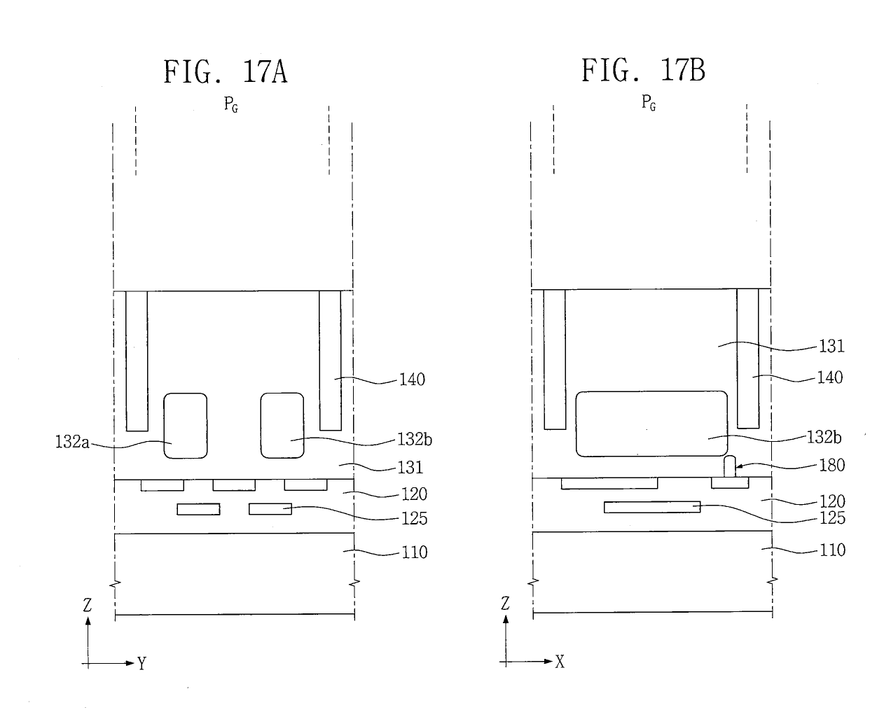

Referring to FIGS. 2, 17A, and 17B, the method of forming the image sensor in accordance with embodiments may include a process of forming a pixel isolation layer 140 between the photoelectric conversion devices 130.

The process of forming the pixel isolation layer 140 may include a process of forming trenches vertically overlapping boundaries between the pixel regions PR, PB, and PR, inside the photoelectric conversion device 130, and a process of filling the trenches with an insulating material.

The photoelectric conversion devices 130 may be surrounded by the pixel isolation layer 140. The pixel isolation layer 140 may be formed inside the first impurity region 131. A lowermost end of the pixel isolation layer 140 may be disposed on a side surface of the second impurity region 132a and on a side surface of the third impurity region 132b.

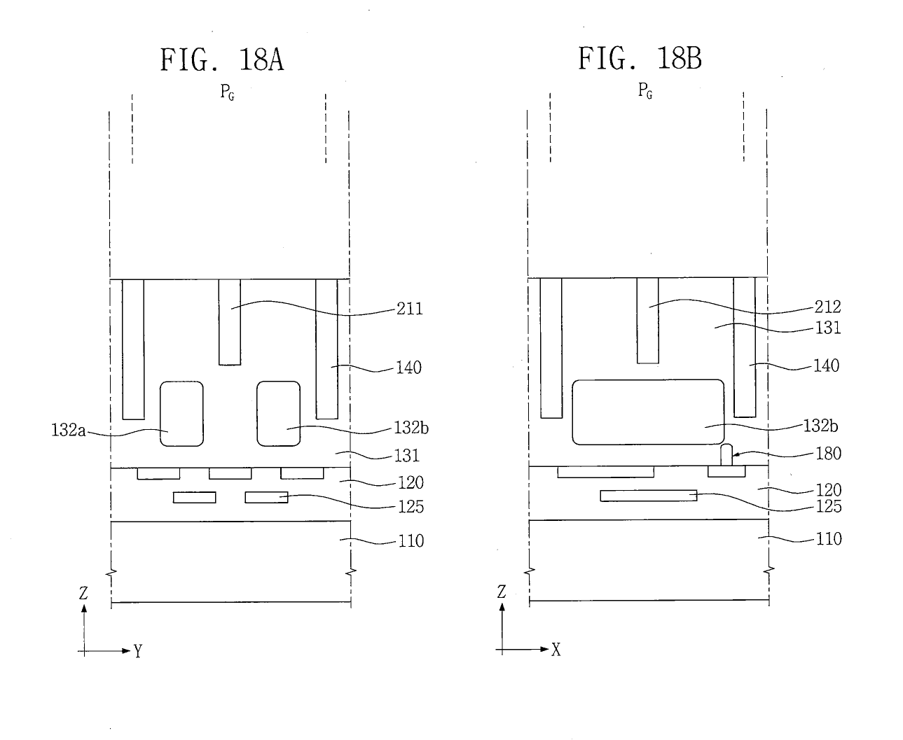

Referring to FIGS. 2, 18A, and 18B, the method of forming the image sensor in accordance with embodiments may include a process of forming the conversion device isolation layer 210 inside the photoelectric conversion device 130.

The process of forming the conversion device isolation layer 210 may include a process of forming a trench intersecting each of the photoelectric conversion devices 130 in a cross-type, and a process of filling the trench with an insulating material.

The conversion device isolation layer 210 may include a first conversion device isolation layer 211 extending in a first direction X and a second conversion device isolation layer 212 extending in a second direction Y perpendicular to the first direction X. The second conversion device isolation layer 212 may be formed with the first conversion device isolation layer 211 at same time. The second conversion device isolation layer 212 may be materially continuous with the first conversion device isolation layer 211.

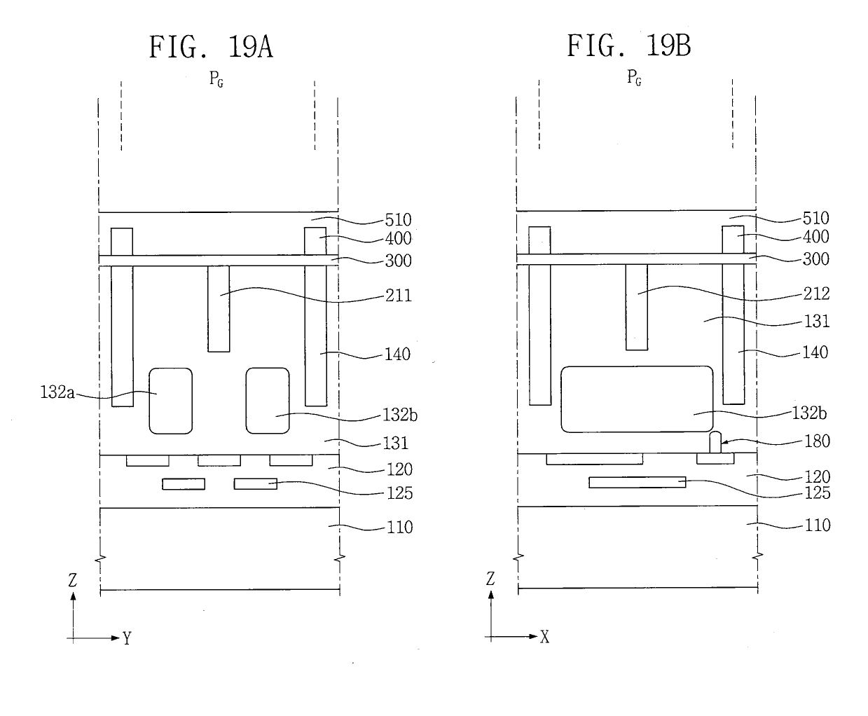

Referring to FIGS. 19A and 19B, the method of forming the image sensor in accordance with embodiments may include a process of forming a buffer layer 300, metal grid 400, and a lower planarization layer 510 on the substrate 110 on which the conversion device isolation layer 210 is formed.

The process of forming the buffer layer 300, the metal grid 400, and the lower planarization layer 510 may include a process of forming the buffer layer 300 on the photoelectric conversion devices 130, the pixel isolation layer 140, and the conversion device isolation layer 210, a process of forming the metal grid 400 on the buffer layer 300 which vertically overlap boundaries between the pixel regions PR, PB, and PR, and a process of forming a lower planarization layer 510 which covers the metal grid 400.

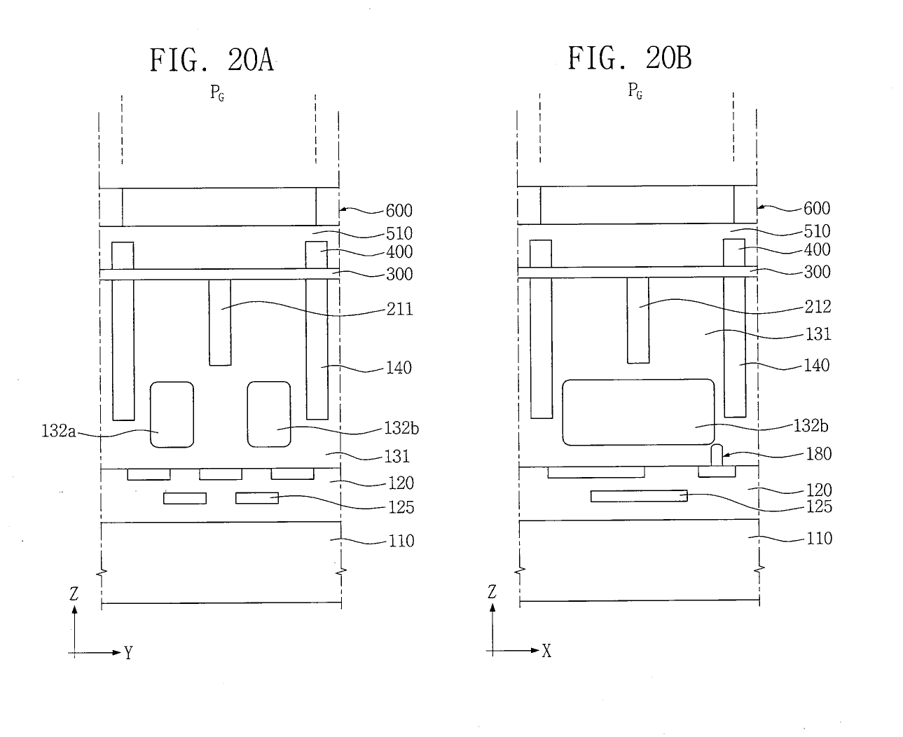

Referring to FIGS. 2, 20A, and 20B, the method of forming the image sensor in accordance with embodiments may include a process of forming color filter 600 on the lower planarization layer 510.

The color filters 600 may vertically overlap the pixel regions PR, PB, and PR. For example, the process of forming the color filter 600 may include a process of forming green color filters vertically overlapping the green pixel region PG, a process of forming blue color filter vertically overlapping the blue pixel region PB and a process of forming red color filters vertically overlapping the red pixel region PR.

Referring to FIGS. 3A and 3B, the method of forming the image sensor in accordance with embodiments may include a process of forming an upper planarization layer 520 and a microlens 700 on the color filter 600.

The microlens 700 may vertically overlap the color filter 600. The microlens 700 may vertically overlap the photoelectric conversion device 130. The microlens 700 may vertically overlap the pixel regions PR, PB, and PR of the substrate 110.

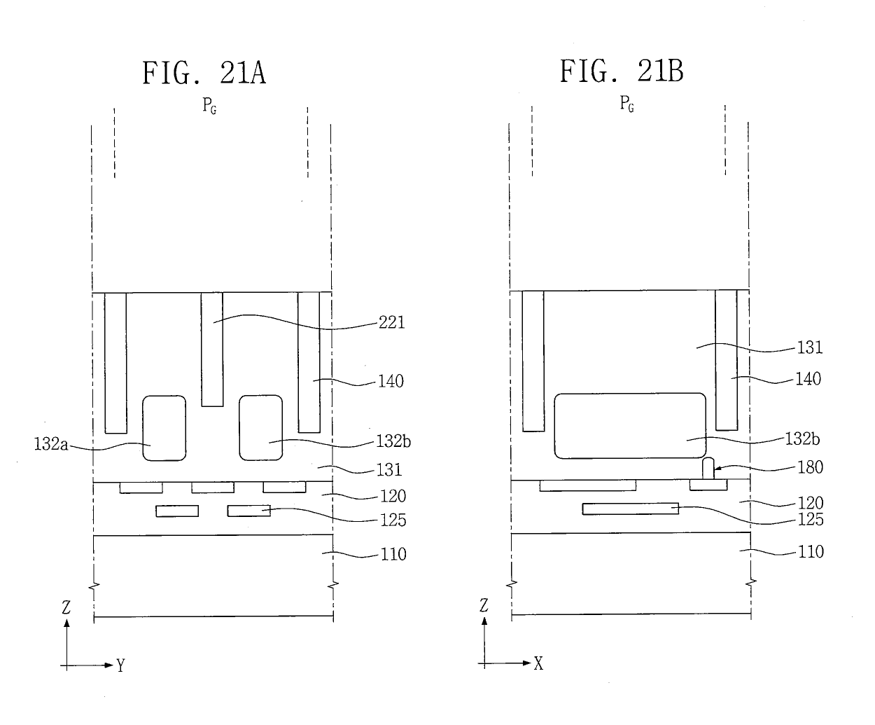

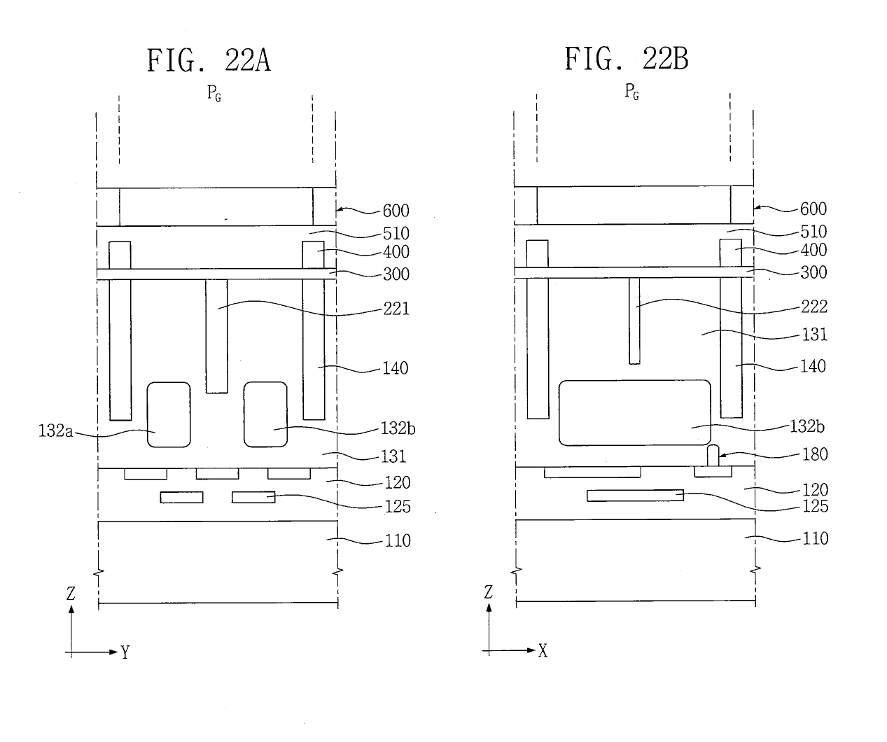

FIGS. 21A, 21B, 22A, and 22B illustrate cross-sectional views of stages in a method of forming an image sensor in accordance with embodiments.

The method of forming the image sensor in accordance with embodiments will be described with referring to FIGS. 1, 5, 7A, 7B, 21A, 21B, 22A, and 22B. Referring to FIGS. 1, 21A, and 21B, the method of forming the image sensor in accordance with embodiments may include a process of preparing a substrate 110 on which an interconnection layer 120 and a photoelectric conversion device 130 are formed, a process of forming a pixel isolation layer 140 vertically overlapping boundaries between pixel regions PR, PB, and PR of the substrate 110 inside a first impurity region 131 of the photoelectric conversion devices 130, and a process of forming a first conversion device isolation layer 221 intersecting the first impurity region 131 in the first direction X between a second impurity region 132a and a third impurity region 132b of the photoelectric conversion device 130.

A process of forming the first conversion device isolation layer 221 may include a process of forming a trench intersecting the first impurity region 131 in the first direction X between the second impurity region 132a and the third impurity region 132b, and a process of filling the trench with an insulating material.

A vertical length of the first conversion device isolation layer 221 may be smaller than that of the pixel isolation layer 140. A lowermost end of the first conversion device isolation layer 221 may be in a higher level than that of the pixel isolation layer 140. A lowermost end of the first conversion device isolation layer 221 may be in a lower level than an uppermost end of the second impurity region 132a and an uppermost end of the third impurity region 132b. A horizontal width of the first conversion device isolation layer 221 may be equal to that of the pixel isolation layer 140.

Referring to FIGS. 5, 22A and 22B, the method of forming the image sensor in accordance with embodiments may include a process of forming a second conversion device isolation layer 222 intersecting the pixel isolation layer 140 and the first conversion device isolation layer 221 in the second direction Y perpendicular to the first direction X, a process of forming a buffer layer 300 on the substrate 110 on which the second conversion device isolation layer 222 is formed, a process of forming metal grid 400 on the buffer layer 300, a process of forming a lower planarization layer 510 which covers the metal grids 400, and a process of forming color filters 600 on the lower planarization layer 510.

The process of forming the second conversion device isolation layer 222 may include a process of forming a trench intersecting the first impurity region 131 in the second direction Y and a process of filling the trench with an insulating material.

A vertical length of the second conversion device isolation layer 222 may be less than that of the first conversion device isolation layer 221. A lowermost end of the second conversion device isolation layer 222 may be in a higher level than that of the first conversion device isolation layer 221.

A horizontal width of the second conversion device isolation layer 222 may be less than that of the first conversion device isolation layer 221. A horizontal width of the second conversion device isolation layer 222 may be less than that of the pixel isolation layer 140.

Referring to FIGS. 7A and 7B, the method of forming the image sensor in accordance with embodiments may include a process of forming the upper planarization layer 520 on the color filters 600 and a process of forming a microlens 700 on the upper planarization layer 520.

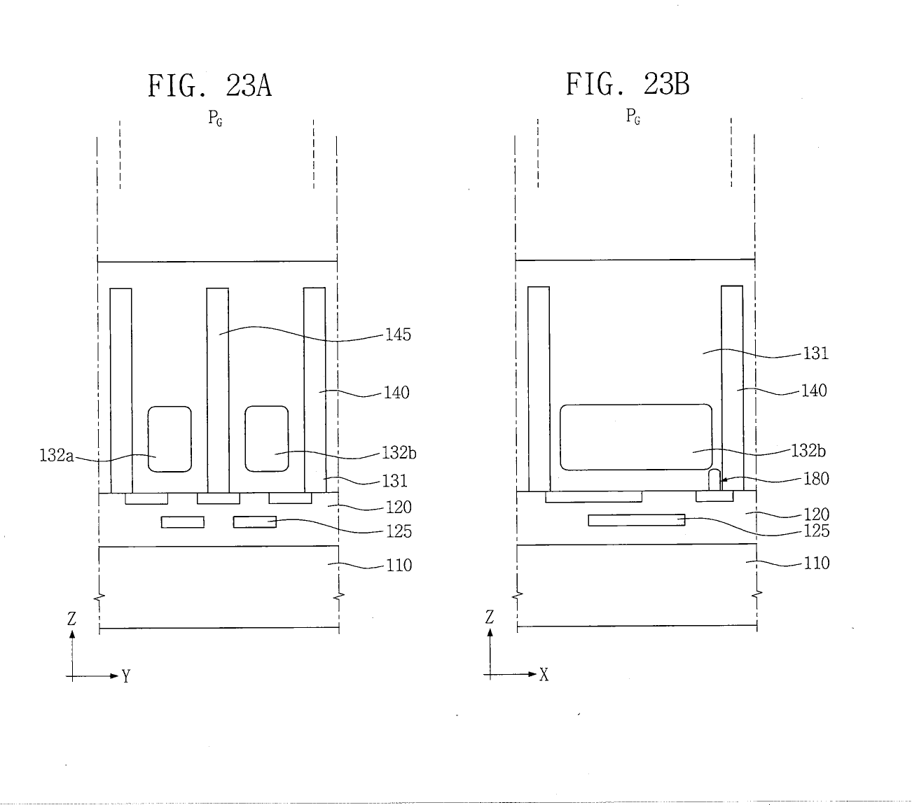

FIGS. 23A to 25A and 23B to 25B illustrate cross-sectional views of stages in a method of forming an image sensor in accordance with embodiments.

The method of forming the image sensor in accordance with embodiments will be described with referring to FIGS. 1, 11, 12A, 12B, 23A to 25A, and 23B to 25B. Referring to FIGS. 1, 23A, and 23B, the method of forming the image sensor in accordance with embodiments may include a process of forming a photoelectric conversion device 130, a process of forming a pixel isolation layer 140, a process of forming an X-axis conversion device isolation layer 145, a process of forming an interconnection layer 120, and a process of forming a substrate 110.

The process of forming the X-axis conversion device isolation layer 145 may include a process of forming a trench extending in the first direction X between a second impurity region 132a and a third impurity region 132b of the photoelectric conversion devices 130, and a process of filling the trench with an insulating material.

Levels of lower surface of the pixel isolation layer 140 and the X-axis conversion device isolation layer 145 may be the same as that of the photoelectric conversion devices 130. Uppermost ends of the pixel isolation layer 140 and the X-axis conversion device isolation layer 145 may be in lower levels than an upper surface of the photoelectric conversion devices 130. For example, a process of forming the pixel isolation layer 140 and a process of forming the X-axis conversion device isolation layer 145 may include a process of forming a trench on a lower surface of the photoelectric conversion device 130.

A vertical length of the X-axis conversion device isolation layer 145 may be the same as the of the pixel isolation layer 140. A horizontal width of the X-axis conversion device isolation layer 145 may be the same as that of the pixel isolation layer 140. For example, the X-axis conversion device isolation layer 145 may be simultaneously formed with the pixel isolation layer 140.

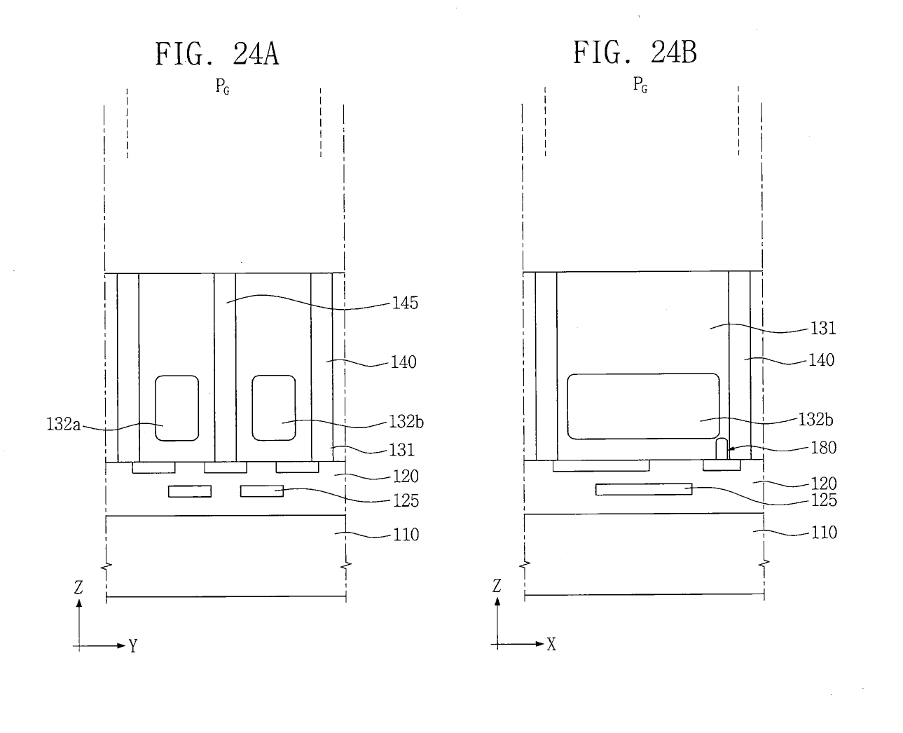

Referring to FIGS. 24A and 24B, the method of forming the image sensor in accordance with embodiments may include a process of exposing an uppermost end of the pixel isolation layer 140 and an uppermost end of the X-axis conversion device isolation layer 145.

The process of exposing the uppermost end of the pixel isolation layer 140 and the uppermost end of the X-axis conversion device isolation layer 145 may include a process of reducing a thickness of the photoelectric conversion devices 130. For example, the process of exposing the uppermost end of the pixel isolation layer 140 and the uppermost end of the X-axis conversion device isolation layer 145 may include a process of grinding an upper surface of the photoelectric conversion device 130.

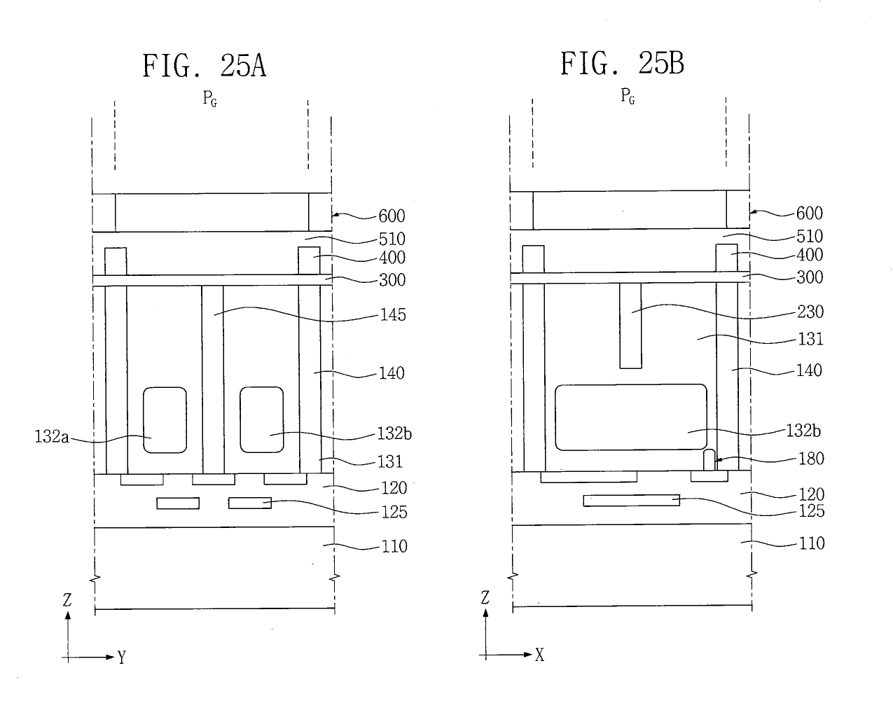

Referring to FIGS. 11, 25A, and 25B, the method of forming the image sensor in accordance with embodiments may include a process of forming the Y-axis conversion device isolation layer 230 intersecting the pixel isolation layer 140 and the X-axis conversion device isolation layer 145 in the second direction Y perpendicular to the first direction X.

A level of an upper surface of the Y-axis conversion device isolation layer 230 may be the same as that of the photoelectric conversion devices 130. A vertical length of the Y-axis conversion device isolation layer 230 may be less than that of the photoelectric conversion devices 130. A horizontal width of the Y-axis conversion device isolation layer 230 may be equal to that of the X-axis conversion device isolation layer 145.

The method of forming the image sensor in accordance with embodiments may include a process of forming a buffer layer 300, a process of forming metal grid 400, a process of forming a lower planarization layer 510, and a process of forming the color filters 600.

Referring to FIGS. 12A and 12B, the method of forming the image sensor in accordance with embodiments may include a process of forming the upper planarization layer 520 on the color filter 600 and a process of forming a microlens 700 on the upper planarization layer 520.

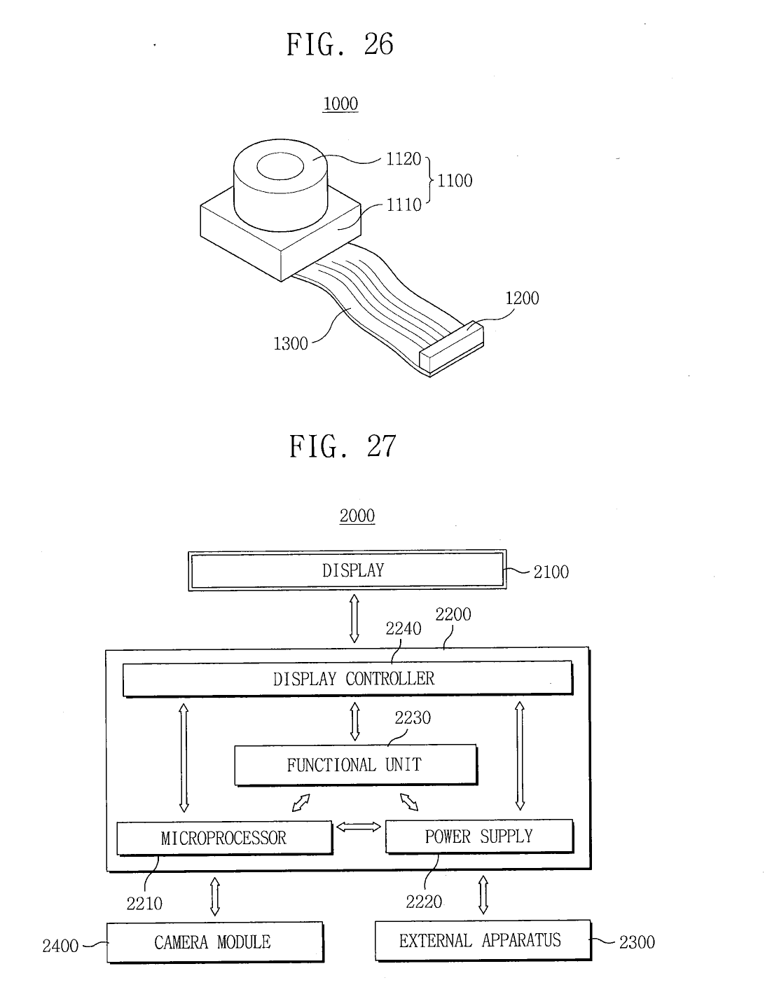

FIG. 26 illustrates a schematic view showing a camera module including electronic devices in accordance with embodiments;

Referring to FIG. 26, the camera module 1000 may include a body 1100, external terminals 1200 and a printed circuit board 1300. The body 1100 may include an image processor 1110 and a lens unit 1120. The image processor 1110 may include electronic apparatuses according to various embodiments of the inventive concepts. For example, the image processor 1110 may include image sensors in accordance with various example embodiments and display devices including the same. Therefore, a color gamut can be expanded in the camera module 1000.

FIG. 27 illustrates a schematic view showing a mobile system including the image sensor in accordance with embodiments.

Referring to FIG. 27, a mobile system 2000 may include a display 2100, a body unit 2200, an external apparatus 2300, and a camera module 2400. The body unit 2200 may include a microprocessor 2210, a power supply 2220, a function unit 2230 and a display controller 2240.

The display 2100 may be electrically connected with the display controller 2240. The display 2100 may display images processed by the display controller 2240. For example, the display 2100 may include liquid crystal display devices.

The body unit 2200 may be a system board or a motherboard including a printed circuit board. The microprocessor 2210, the power supply 2220, the function unit 2230, and the display controller 2240 may be mounted or installed on the body unit 2200.

The microprocessor 2210 may be supplied with a voltage from the power supply 2220 and may control the function unit 2230 and the display controller 2240. The power supply 2220 may receive a constant voltage from an external power source, etc., divide the voltage into various levels of desired or required voltages, and supply those voltages to the microprocessor 2210, the function unit 2230, and the display controller 2240.

The power supply 2220 may include a power management IC (PMIC). The PMIC may efficiently supply voltages to the microprocessor 2210, the function unit 2230, and the display controller 2240.

The function unit 2230 may perform various functions of the mobile system 2000. For example, the function unit 2230 may include several components which perform wireless communication functions, such as outputting an image to the display 2100, outputting a voice to a speaker, etc., by dialing or communicating with the external apparatus 2300. For example, the function unit 2230 may serve as an image processor.

The function unit 2230 may serve as a memory card controller when the mobile system 2000 is connected to a memory card for expansion of the memory capacity. The function unit 2230 may serve as an interface controller when the mobile system 2000 includes a Universal Serial Bus (USB) in order to expand functions.

The display 2100 and the camera module 2400 may include electronic apparatuses having an image sensor in accordance with various example embodiments. Therefore, a color gamut can be expanded in the mobile system 2000.

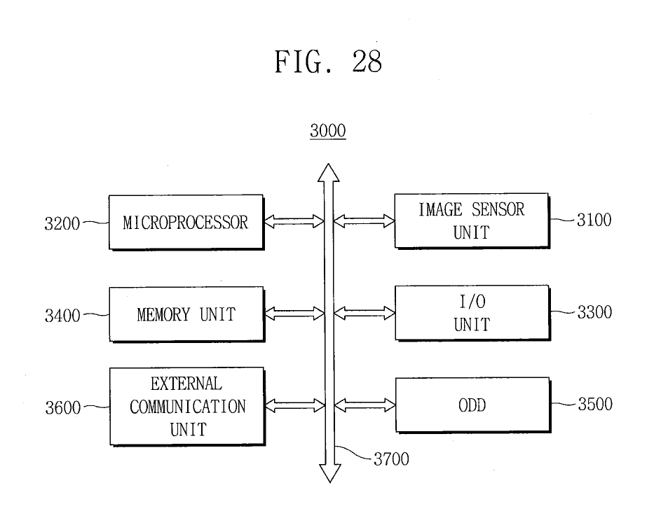

FIG. 28 illustrates a schematic view showing an electronic system including the image sensor in accordance with embodiments.

Referring to FIG. 28, the electronic system 3000 may include an image sensor unit 3100, a microprocessor 3200, an input/output unit 3300, a memory 3400 and a bus 3700.

The image sensor unit 3100 may generate electrical signals corresponding to incident light and transmit it to the microprocessor 3200. The microprocessor 3200 may program and control the electronic system 3000. The input/output unit 3300 may perform data communication using the bus 3700. The input/output unit 3300 may be used to input or output data to or from the electronic system 3000. The memory 3400 may store codes for booting the microprocessor 3200, data processed by the microprocessor 3200, or external input data. The memory 3400 may include a controller and memories. The image sensor unit 3100, the microprocessor 3200, the input/output unit 3300, and the memory 3400 may communicate through the bus 3700.

The electronic system 3000 may further include an optical disk drive (ODD) 3500 and an external communication unit 3600. The ODD 3500, for example, may include a CD-ROM driver, a DVD driver, etc. The external communication unit 3600 may include a modem, a local area network (LAN) card, or a USB, an external memory driver, a wireless broadband (WiBro) communication device, an infrared communication device, etc.

The image sensor unit 3100 may include an electronic system including the image sensor in accordance with various example embodiments. Therefore, a color gamut can be expanded in the electronic system 3000.

In the image sensor according to the embodiments of the inventive concepts, the light diffused and reflected by the conversion device isolation layer intersecting the photoelectric conversion device can be uniformly applied to adjacent pixel regions. Accordingly, in the image sensor according to the embodiments of the inventive concepts, cross-talk caused by a conversion device isolation layer can be uniformly generated in adjacent pixel regions. Therefore, in the image sensor according to the embodiments of the inventive concepts, a color gamut can be expanded.

The foregoing is illustrative of embodiments and is not to be construed as limiting thereof. Although a few embodiments have been described, those skilled in the art will readily appreciate that many modifications are possible without materially departing from the novel teachings and advantages.

What is claimed is:

1. An image sensor comprising:
a first conductivity type first impurity region surrounded by a pixel isolation layer;
a first conversion device isolation layer intersecting the first impurity region in a first direction, the first conversion device isolation layer including a first side surface and a second side surface opposite the first side surface;
a second conductivity type second impurity region disposed inside the first impurity region and disposed on the first side surface of the first conversion device isolation layer;
a second conductivity type third impurity region disposed inside the first impurity region and disposed on the second side surface of the first conversion device isolation layer; and
a second conversion device isolation layer intersecting the first impurity region in a second direction perpendicular to the first direction.

2. The image sensor of claim 1, wherein the first conversion device isolation layer bisects the first impurity region in the second direction and the second conversion device isolation layer bisects the first impurity region in the first direction.

3. The image sensor of claim 1, wherein the first conversion device isolation layer and the second conversion device isolation layer include an insulating material.

4. The image sensor of claim 3, wherein the second conversion device isolation layer includes a same material as the first conversion device isolation layer.

5. The image sensor of claim 1, wherein a horizontal width of the second conversion device isolation layer is equal to a horizontal width of the first conversion device isolation layer.

6. The image sensor of claim 5, wherein a horizontal width of the first conversion device isolation layer is equal to a horizontal width of the pixel isolation layer.

7. An image sensor comprising:
a substrate including a pixel region;
a first conductivity type first impurity region disposed on the substrate, the first impurity region vertically overlapping the pixel region;
a second conductivity type second impurity region extending in a first direction inside the first impurity region;
a second conductivity type third impurity region extending in the first direction inside the first impurity region, the third impurity region separated from the second impurity region in a second direction perpendicular to the first direction;
a first conversion device isolation layer intersecting the first impurity region in the first direction between the second impurity region and the third impurity region; and
a second conversion device isolation layer intersecting the first impurity region in the second direction.

8. The image sensor of claim 7, wherein a level of an upper surface of the first conversion device isolation layer and a level of an upper surface of the second conversion device isolation layer is equal to a level of an upper surface of the first impurity region.

9. The image sensor of claim 7, wherein a lowermost end of the second conversion device isolation layer is higher than an uppermost end of the second impurity region and an uppermost end of the third impurity region.

10. The image sensor of claim 9, wherein a level of the uppermost end of the third impurity region is equal to a level of the uppermost end of the second impurity region.

11. The image sensor of claim 9, wherein a lowermost end of the first conversion device isolation layer is lower than the lowermost end of the second conversion device isolation layer.

12. The image sensor of claim 11, wherein a vertical length of the first conversion device isolation layer is equal to a vertical length of the first impurity region.

13. The image sensor of claim 7, further comprising:
a pixel isolation layer disposed on the substrate and vertically overlapping a boundary of the pixel region,
wherein a horizontal width of the second conversion device isolation layer is less than a horizontal width of the pixel isolation layer.

14. The image sensor of claim 13, wherein a horizontal width of the first conversion device isolation layer is equal to a horizontal width of the pixel isolation layer.

15. The image sensor of claim 7, further comprising:
a microlens disposed on the first impurity region and vertically overlapping the pixel region.

16. An image sensor comprising:
a substrate including pixel regions;
photoelectric conversion devices disposed on the pixel regions of the substrate; and
a conversion device isolation layer intersecting the photoelectric conversion devices in a cross-type,
wherein the conversion device isolation layer includes an insulating material.

17. The image sensor of claim 16, further comprising:
a pixel isolation layer vertically overlapping boundaries between the pixel regions and surrounding the photoelectric conversion devices,
wherein a vertical length of the conversion device isolation layer is less than a vertical length of the pixel isolation layer.

18. The image sensor of claim 17, wherein the conversion device isolation layer includes a first conversion device isolation layer extending in a first direction and a second conversion device isolation layer extending in a second direction perpendicular to the first direction,
wherein a vertical length of the second conversion device isolation layer is different from a vertical length of the first conversion device isolation layer.

19. The image sensor of claim 16, further comprising:
a pixel isolation layer vertically overlapping boundaries between the pixel regions and surrounding the photoelectric conversion devices,
wherein a horizontal width of the conversion device isolation layer is less than a horizontal width of the pixel isolation layer.

20. The image sensor of claim 19, wherein the conversion device isolation layer includes a first conversion device isolation layer extending in a first direction and a second conversion device isolation layer extending in a second direction perpendicular to the first direction,
wherein a horizontal width of the second conversion device isolation layer is equal to a horizontal width of the first conversion device isolation layer.
